(19) United States
(12) Patent Application Publication
(10) Pub. No.: US 2025/0031538 A1
(43) Pub. Date: Jan. 23, 2025

(54) DISPLAY PANEL AND DISPLAY DEVICE

(71) Applicants: CHENGDU BOE OPTOELECTRONICS TECHNOLOGY CO., LTD., Sichuan (CN); TECHNOLOGY GROUP CO., LTD., Beijing (CN)

(72) Inventors: Rong WANG, Beijing (CN); Cong FAN, Beijing (CN); Xiangdan DONG, Beijing (CN); Fan HE, Beijing (CN); Ming HU, Beijing (CN); Youngyik KO, Beijing (CN); Haijun QIU, Beijing (CN)

(21) Appl. No.: 18/713,096

(22) PCT Filed: Nov. 23, 2021
(86) PCT No.: PCT/CN2021/132507

§ 371 Date: May 23, 2024

(51) Int. Cl. H10K 59/131; H10K 59/121

(52) U.S. Cl. CPC H10K 59/131; H10K 59/1213

(57) ABSTRACT

A display panel includes a display area and a peripheral area at least partially surrounding the display area. Along a first direction, the display area includes a first display area and a second display area located on both sides of the first display area. The display panel further includes a plurality of pads located in the peripheral area; a plurality of data lines located in the display area and extending along a second direction, where the plurality of data lines include a plurality of first data lines located in the first display area and a plurality of second data lines located in the second display area; and a plurality of transition lines located in the display area and electrically connected to the plurality of second data lines and the plurality of pads.

### TECHNICAL FIELD

This disclosure relates to the field of display technology, and in particular, to a display panel and a display device.

### BACKGROUND

OLED (Organic Light Emitting Diode) display panels have the advantages of self-illumination, wide color gamut, high contrast, flexibility, high-speed response and the like, and have broad application prospects. Currently, OLED display panels have higher and higher requirements for ultra-narrow lower bezel.

It is to be noted that the above information disclosed in this background section is only for enhancing understanding the context of the disclosure and, therefore, may contain information that does not form the prior art that is already known to those skilled in the art.

### SUMMARY

The purpose of this disclosure is to overcome the shortcomings of the above-mentioned prior art, provide a display panel and a display device, and reduce the lower bezel of the display panel.

According to a first aspect of this disclosure, a display panel is provided and includes a display area and a peripheral area at least partially surrounding the display area; where, along a first direction, the display area of the display panel includes a first display area and a second display area located on both sides of the first display area; and the display panel includes:
a plurality of pads located in the peripheral area;
a plurality of data lines located in the display area and extending along a second direction, where the plurality of data lines include a plurality of first data lines located in the first display area and a plurality of second data lines located in the second display area, and the plurality of first data lines are electrically connected to the plurality of pads; and a plurality of transition lines located in the display area and electrically connected to the plurality of second data lines and the plurality of pads, where the transition lines include first transition lines extending along the first direction and second transition lines extending along the second direction;
where at least one of the second transition lines is provided between two adjacent ones of the first data lines, and the first direction intersects with the second direction.

According to some embodiments of this disclosure, the second transition lines are arranged into a plurality of second transition line groups, and each of the second transition line groups includes at least two adjacent ones of the second transition lines;
the plurality of first data lines are arranged into a plurality of first data line groups, and each of the first data line groups includes multiple adjacent ones of the first data lines;
in at least a partial area of the first display area, the first data line groups and the second transition line groups are alternately arranged one by one.

According to some embodiments of this disclosure, the second transition lines include first sub-lines and second sub-lines, and the first sub-lines and the second sub-lines are arranged on different conductive layers;
in at least a partial area of the first display area, the first sub-lines and the second sub-lines are alternately arranged.

According to some embodiments of this disclosure, the display panel further includes a plurality of pad connection lines;
where the plurality of pad connection lines are located in the peripheral area and electrically connected to the plurality of pads; the second transition lines are electrically connected to the pads through the pad connection lines; and the first data lines are electrically connected to the pads through the pad connecting lines.

According to some embodiments of this disclosure, a side of the second display area close to the plurality of pads is provided with an arc-shaped top corner.

According to some embodiments of this disclosure, the display area is arranged symmetrically with respect to a central axis extending along the second direction;
in two adjacent ones of the second data lines, compared with one of the second transition lines corresponding to one of the two adjacent ones closer to the central axis, another one of the second transition lines corresponding to another one of the two adjacent ones farther away from the central axis is arranged farther away from the central axis.

According to some embodiments of this disclosure, the display area is arranged symmetrically with respect to a central axis extending along the second direction;
in two adjacent ones of the second data lines, compared with one of the first transition lines corresponding to one of the two adjacent ones closer to the central axis, another one of the first transition lines corresponding to another one of the two adjacent ones farther away from the central axis is arranged closer to the pads.

According to some embodiments of this disclosure, the display panel includes a base substrate, a driving circuit layer and a pixel layer stacked in sequence, where the driving circuit layer includes a transistor layer and a source-drain metal layer stacked with each other, and the source-drain metal layer is sandwiched between the transistor layer and the pixel layer; the transition lines are provided on the source-drain metal layer.

According to some embodiments of this disclosure, the source-drain metal layer includes a first source-drain metal layer and a second source-drain metal layer sequentially stacked on a side of the transistor layer away from the base substrate; the data lines are provided on the second source-drain metal layer;
the first transition lines are provided on the first source-drain metal layer; and
the second transition lines are provided on the second source-drain metal layer and/or the first source-drain metal layer.

According to some embodiments of this disclosure, the transistor layer is provided with a gate layer;
the driving circuit layer further includes an electrode initialization voltage line extending along the first direction; the electrode initialization voltage line is configured to load an electrode reset voltage for resetting sub-pixels of the display panel; the electrode initialization voltage line includes a first initialization line and a second initialization line alternately connected; the first initialization line is provided on the gate layer; and the second initialization line is provided on the first source-drain metal layer;
part of the second transition lines are provided on the first source-drain metal layer, and the second transition lines located on the first source-drain metal layer overlap with the first initialization line.

According to some embodiments of this disclosure, the source-drain metal layer includes a first source-drain metal layer, a second source-drain metal layer and a third source-drain metal layer sequentially stacked on a side of the transistor layer away from the base substrate; the data lines are provided on the second source-drain metal layer; and the transition lines are provided on the third source-drain metal layer.

According to some embodiments of this disclosure, the transistor layer is provided with thin film transistors of driving circuits, and the transition lines do not overlap with the thin film transistors.

According to some embodiments of this disclosure, the driving circuit layer includes driving circuit islands distributed in an array, and any one of the driving circuit islands includes one or more driving circuit regions corresponding to respective one of the driving circuits; at least part of the thin film transistors of the driving circuits are provided in corresponding ones of the driving circuit regions;
the transition lines are provided in a gap between the driving circuit islands.

According to some embodiments of this disclosure, among two adjacent ones of the driving circuits in the second direction, at least one thin film transistor of the driving circuit in an upper row is located in one of the driving circuit regions corresponding to the driving circuit in a lower row, and remaining thin film transistors of the driving circuit in the upper row are located in one of the driving circuit regions corresponding to the driving circuit in the upper row.

According to some embodiments of this disclosure, the driving circuits are arranged into a plurality of driving circuit groups, and each of the driving circuit groups includes two of driving circuits that are adjacent and mirrored along the first direction.

According to some embodiments of this disclosure, the driving circuit regions in the driving circuit islands are arranged in multiple rows and multiple columns.

According to some embodiments of this disclosure, the driving circuit regions in the driving circuit islands are arranged in two rows and four columns.

According to some embodiments of this disclosure, the transition lines include first transition lines extending along the first direction and second transition lines extending along the second direction;
a number of the second transition lines between two adjacent columns of the driving circuit islands is no more than six.

According to some embodiments of this disclosure, the display area is arranged symmetrically with respect to a central axis extending along the second direction, and the first display area includes two arrangement areas respectively located on both sides of the central axis;
the second transition lines are arranged into a plurality of second transition line groups; respective second transition lines in any one of the second transition line groups are arranged adjacently in sequence and located between two adjacent columns of the driving circuit islands; any two adjacent ones of the second transition line groups are separated by a column of the driving circuit islands;
any one of the second transition line groups includes one or more of the second transition lines.

According to some embodiments of this disclosure, the transition lines are arranged symmetrically with respect to the central axis; and the first data lines are arranged symmetrically with respect to the central axis.

According to some embodiments of this disclosure, in at least one of the arrangement areas, numbers of the second transition lines in respective second transition line groups are the same; or in at least one of the arrangement areas, one of the second transition line groups has a smaller number of the second transition lines, and remaining second transition line groups have more and same number of the second transition lines.

According to some embodiments of this disclosure, in at least one of the arrangement areas, respective second transition line groups are evenly distributed along the first direction.

According to some embodiments of this disclosure, in at least one of the arrangement areas, one of the second transition line groups farthest from the central axis is arranged adjacent to one column of the driving circuit islands farthest from the central axis. According to some embodiments of this disclosure, in at least one of the arrangement areas, one of the second transition line groups closest to the central axis is arranged adjacent to one column of the driving circuit islands closest to the central axis.

According to some embodiments of this disclosure, the transition lines include first transition lines extending along the first direction and second transition lines extending along the second direction;
a number of the first transition lines between two adjacent rows of the driving circuit islands is no more than three.

According to some embodiments of this disclosure, any one of the second data lines is electrically connected to the pad connection line through the transition line; any one of the first data lines is directly and electrically connected to the pad connection line.

According to a second aspect of this disclosure, a display device is provided and includes the forgoing display panel.

It is to be understood that both the foregoing general description and the following detailed description are exemplary and explanatory only and are not restrictive of this disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Apparently, the drawings in the following description are only some embodiments of this disclosure, and those skilled in the art may obtain other drawings according to these drawings without creative efforts.

FIG. 1 is a schematic structural view of a display panel in some embodiments of this disclosure.

FIG. 2 is a schematic diagram illustrating a partial structure of a display panel in some embodiments of this disclosure.

FIG. 3 is a schematic diagram illustrating a partial structure of a display panel in some embodiments of this disclosure.

FIG. 4 is a schematic diagram illustrating a partial structure of a display panel in some embodiments of this disclosure.

FIG. 5 is a schematic diagram illustrating positions of a first transition line area and a second transition line area in some embodiments of this disclosure.

FIG. 6 is a schematic diagram illustrating positions of a first transition line area and a second transition line area in some embodiments of this disclosure.

FIG. 7 is a schematic diagram illustrating positions of a first transition line area and a second transition line area in some embodiments of this disclosure.

FIG. 8 is a schematic diagram illustrating distribution of driving circuit islands in some embodiments of this disclosure.

FIG. 9 is a schematic diagram illustrating distribution of driving circuit islands and second transition lines in some embodiments of this disclosure.

FIG. 10 is a schematic diagram illustrating distribution of driving circuit islands and second transition lines in some embodiments of this disclosure.

FIG. 11 is a schematic diagram illustrating distribution of driving circuit islands and second transition lines in some embodiments of this disclosure.

FIG. 12 is a schematic diagram illustrating distribution of driving circuit islands and second transition lines in some embodiments of this disclosure.

FIG. 13 is a schematic diagram illustrating distribution of driving circuit islands and second transition lines in some embodiments of this disclosure.

FIG. 14 is a schematic diagram illustrating distribution of driving circuit islands and second transition lines in some embodiments of this disclosure.

FIG. 15 is a schematic diagram illustrating distribution of driving circuit islands and second transition lines in some embodiments of this disclosure.

FIG. 16 is a schematic diagram illustrating a film layer structure of a display panel in some embodiments of this disclosure.

FIG. 17 is an equivalent circuit diagram of a driving circuit in some embodiments of this disclosure.

FIG. 18 is a schematic diagram illustrating a driving sequence of a driving circuit in some embodiments of this disclosure.

FIG. 19 is a schematic diagram illustrating a partial structure of a light-shielding layer in a driving circuit region in some embodiments of this disclosure.

FIG. 20 is a schematic diagram illustrating a partial structure of a light-shielding layer in a display area in some embodiments of this disclosure.

FIG. 21 is a schematic diagram illustrating a partial structure of a low-temperature polysilicon semiconductor layer and a metal oxide semiconductor layer in a driving circuit region in some embodiments of this disclosure.

FIG. 22 is a schematic diagram illustrating a partial structure of a low-temperature polysilicon semiconductor layer in a display area in some embodiments of this disclosure.

FIG. 23 is a schematic diagram illustrating a partial structure of a metal oxide semiconductor layer in a display area in some embodiments of this disclosure.

FIG. 24 is a schematic diagram illustrating a partial structure of a first gate layer in a driving circuit region in some embodiments of this disclosure.

FIG. 25 is a schematic diagram illustrating a partial structure of a first gate layer in a display area in some embodiments of this disclosure.

FIG. 26 is a schematic diagram illustrating a partial structure of a second gate layer in a driving circuit region in some embodiments of this disclosure.

FIG. 27 is a schematic diagram illustrating a partial structure of a second gate layer in a display area in some embodiments of this disclosure.

FIG. 28 is a schematic diagram illustrating a partial structure of a third gate layer in a driving circuit region in some embodiments of this disclosure.

FIG. 29 is a schematic diagram illustrating a partial structure of a third gate layer in a display area in some embodiments of this disclosure.

FIG. 30 is a schematic diagram illustrating a partial structure of a first source-drain metal layer in a driving circuit region in some embodiments of this disclosure.

FIG. 31 is a schematic diagram illustrating a partial structure of a first source-drain metal layer in a display area in some embodiments of this disclosure.

FIG. 32 is a schematic diagram illustrating a partial structure of a second source-drain metal layer in a driving circuit region in some embodiments of this disclosure.

FIG. 33 is a schematic diagram illustrating a partial structure of a second source-drain metal layer in a display area in some embodiments of this disclosure.

### DETAILED DESCRIPTION

Exemplary embodiments will now be described more fully with reference to the accompanying drawings. Exemplary embodiments may, however, be embodied in many forms and should not be construed as limited to the embodiments set forth herein. Rather, these embodiments are provided so that this disclosure will be thorough and complete, and will fully convey the concept of exemplary embodiments to those skilled in the art. The same reference numerals in the drawings denote the same or similar structures, and thus their detailed descriptions will be omitted. Furthermore, the drawings are merely schematic illustrations of this disclosure and are not necessarily drawn to scale.

Although relative terms such as “upper” and “lower” are used in this specification to describe the relative relationship of one component as illustrated to another component, these terms are used in this specification only for convenience, for example, according to directions in the example described with reference to the drawings. It will be appreciated that if the illustrated device is turned over so that it is upside down, then components described as being “upper” will become components that are “lower”. When a structure is “on” another structure, it may mean that the structure is integrally formed on another structure, or that the structure is “directly” arranged on another structure, or that the structure is “indirectly” arranged on another structure through still another structure.

The terms “a”, “an”, “the”, “said” and “at least one” are used to indicate the presence of one or more elements/components/etc.; the terms “comprise/include” and “have” are used to indicate an open inclusion and means that there may be additional elements/components/etc. in addition to the listed elements/components/etc.; the terms “first”, “second” and “third” etc. are only used as a marker, rather than a limit on the number of a related object.

This disclosure provides a display panel and a display device provided with the display panel. Referring to FIG. 16, the display panel includes a base substrate BP, a driving circuit layer DR and a pixel layer EE stacked in sequence. In some embodiments, the pixel layer EE is provided with sub-pixels distributed in an array, and the driving circuit layer DR is provided with driving circuits corresponding to the sub-pixels one by one. The respective sub-pixels are configured to realize display under the driving of the corresponding driving circuits.

In the driving circuit layer, the display panel may be provided with scanning lines extending along a first direction (generally the row direction) and data lines DL extending along a second direction (generally the column direction); and scanning may be implemented row by row to realize image display. Correspondingly, the respective driving circuits may be arranged into driving circuit rows extending along the first direction and driving circuit columns extending along the second direction. The first direction intersects with (e.g., is perpendicular to) the second direction.

Referring to FIG. 16, from the perspective of film layer stacking, the display panel of this disclosure may include the base substrate BP, the driving circuit layer DR, and the pixel layer EE stacked in sequence.

The base substrate may be a base substrate of inorganic material, or a base substrate of organic material. For example, in some embodiments of this disclosure, the material of the base substrate may be glass material such as soda-lime glass, quartz glass, sapphire glass; or may be metal material such as stainless steel, aluminum, nickel, and the like. In some other embodiments of this disclosure, the material of the base substrate may be polymethyl methacrylate (PMMA), polyvinyl alcohol (PVA), polyvinyl phenol (PVP), polyether sulfone (PES), polyimide, polyamide, polyacetal, polycarbonate (PC), polyethylene terephthalate (PET), polyethylene naphthalate (PEN) or combinations thereof. In some other embodiments of this disclosure, the base substrate may also be a flexible base substrate. For example, the material of the base substrate may be polyimide (PI). The base substrate may also be a composite of multi-layer materials. For example, in some embodiments of this disclosure, the base substrate may include a bottom film, a pressure-sensitive adhesive layer, a first polyimide layer and a second polyimide layer.

In this disclosure, the driving circuit layer is provided with driving circuits for driving sub-pixels. In the driving circuit layer, any driving circuit may include a transistor and a storage capacitor. Further, the transistor may be a thin film transistor, and the thin film transistor may be selected from top gate thin film transistor, bottom gate thin film transistor or double gate thin film transistor. The material of the active layer of the thin film transistor may be amorphous silicon semiconductor material, low temperature polysilicon semiconductor materials, metal oxide semiconductor materials, organic semiconductor materials or other types of semiconductor materials. The thin film transistors may be N-type thin film transistors or P-type thin film transistors.

It may be understood that among the various transistors in the driving circuit, the types of any two transistors may be the same or different. Exemplarily, in a driving circuit according to some embodiments, some transistors may be N-type transistors and some transistors may be P-type transistors. As another example, in a driving circuit according to some other embodiments, the material of the active layer of some transistors may be low-temperature polysilicon semiconductor, and the material of the active layer of some transistors may be metal oxide material semiconductor.

The transistor may have a first terminal, a second terminal and a control terminal, where one of the first and second terminals may be the source of the transistor and the other may be the drain of the transistor, and the control terminal may be the gate of the transistor. It may be understood that the source and the drain of the transistor are two opposite concepts that may be interchanged. When the working state of the transistor changes, for example, the direction of the current changes, the source and the drain of the transistor may be interchanged.

In this disclosure, the driving circuit layer may include a transistor layer, an interlayer dielectric layer ILD, and a source-drain metal layer sequentially stacked on the base substrate. In some embodiments, the transistor layer is provided with an active layer and a gate of the transistor, and the source-drain metal layer is electrically connected with the source and drain of the transistor. Optionally, the transistor layer may include a semiconductor layer, a gate insulating layer, and a gate layer stacked between the base substrate BP and the interlayer dielectric layer. Herein, the positional relationship of respective film layers may be determined according to the film layer structure of the thin film transistor. In some embodiments, the semiconductor layer may be used to form the active layer of the transistor, and the active layer of the semiconductor includes a channel region as well as a source and a drain located on both sides of the channel region. Herein, the channel region may maintain semiconductor characteristics, and the semiconductor material of the source and drain is partially or completely conductive. The gate layer may be used to form gate layer lines such as scanning lines, may also be used to form gates of transistors, and may also be used to form part or all of electrode plates of storage capacitors. The source-drain metal layer may be used to form source-drain metal layer lines such as data lines and power lines.

For example, in some embodiments of this disclosure, the driving circuit layer may include a semiconductor layer, a gate insulating layer, a gate layer, an interlayer dielectric layer, and a source-drain metal layer stacked in sequence, and the thin film transistor thus formed is a top-gate thin film transistor.

For another example, in some embodiments of this disclosure, the driving circuit layer may include a gate layer, a gate insulating layer, a semiconductor layer, an interlayer dielectric layer, and a source-drain metal layer stacked in sequence, and the thin film transistor thus formed is a bottom-gate thin film transistor.

The gate layer may be a one-layer gate layer, or a two-layer or three-layer gate layer. Exemplarily, in some embodiments, referring to FIG. 16, the gate layer may include a first gate layer LG1, a second gate layer LG2 and a third gate layer LG3. The semiconductor layer may be a one-layer semiconductor layer, or a two-layer semiconductor layer. Exemplarily, in some embodiments, referring to FIG. 16, the semiconductor layer may include a low temperature polysilicon semiconductor layer LPoly and a metal oxide semiconductor layer LOxide. It may be understood that when the gate layer or the semiconductor layer has a multi-layer structure, the insulating layer in the transistor layer may be increased or decreased accordingly. Exemplarily, in some embodiments of this disclosure, referring to FIG. 16, the transistor layer may include a low-temperature polysilicon semiconductor layer LPoly, a first gate insulating layer LGI1, a first gate layer LG1, a second insulating buffer layer Buff2 (e.g., an inorganic layer such as silicon nitride, silicon oxide and the like), a second gate layer LG2, a second gate insulating layer LGI2, a metal oxide semiconductor layer LOxide, a third gate insulating layer LGI3, a third gate layer LG3 and the like.

The source-drain metal layer may be a one-layer source-drain metal layer, or a two-layer or three-layer source-drain metal layer. Exemplarily, in some embodiments of this disclosure, referring to FIG. 16, the source-drain metal layer may include a first source-drain metal layer LSD1 and a second source-drain metal layer LSD2. In some embodiments, a passivation layer PVX and a first planarization layer PLN1 may be provided between the first source-drain metal layer LSD1 and the second source-drain metal layer LSD2, and a second planarization layer PLN2 is provided between the LSD2 and the pixel layer.

Optionally, the driving circuit layer may also include a first insulating buffer layer Buff1 provided between the base substrate BP and the semiconductor layer, and the semiconductor layer, the gate layer and the like are located on the side of the first insulating buffer layer Buff1 away from the base substrate. The material of the first insulating buffer layer Buff1 may be inorganic insulating material such as silicon oxide and silicon nitride. The buffer material layer may include one layer of inorganic material, or multiple stacked layers of inorganic materials.

Optionally, referring to FIG. 16, a light-shielding layer LBSM may also be provided between the first insulating buffer layer Buff1 and the base substrate BP, and the light-shielding layer LBSM may overlap with channel regions of at least part of the transistors, so as to shield the light irradiated at the transistors, thereby making the electrical characteristics of the transistors stable.

The pixel layer is provided with light-emitting elements (serving as sub-pixels) distributed in an array, and each light-emitting element emits light under the control of the driving circuit. In this disclosure, the light-emitting element may be an organic electroluminescent diode (OLED), a micro light-emitting diode (Micro LED), a quantum dot-organic electroluminescent diode (QD-OLED), a quantum dot light-emitting diode (QLED) or other types of light-emitting elements. Exemplarily, in some embodiments of this disclosure, the light-emitting element is an OLED, and the display panel is an OLED display panel. A possible structure of the pixel layer is exemplarily introduced as follows by taking the light-emitting element being an OLED as an example.

Optionally, referring to FIG. 16, the pixel layer may be provided on the side of the driving circuit layer away from the base substrate, which may include a pixel electrode layer LAn, a pixel definition layer PDL, and a support pillar layer (not shown in FIG. 16), an organic light-emitting functional layer LEL and a common electrode layer LCOM staked in sequence. In some embodiments, the pixel electrode layer LAn has a plurality of pixel electrodes in the display area of the display panel. The pixel definition layer has a plurality of through pixel openings corresponding to the plurality of pixel electrodes, one by one, in the display area, and any one of the pixel openings exposes at least a partial area of a corresponding pixel electrode. The support pillar layer includes a plurality of support pillars in the display area, and the support pillars are located on the surface of the pixel definition layer away from the base substrate, so as to support a fine metal mask (FMM) during the evaporation process. The organic light-emitting functional layer at least covers the pixel electrodes exposed by the pixel definition layer. Herein, the organic light-emitting functional layer may include an organic electroluminescent material layer, and may include one or more of a hole injection layer, a hole transport layer, an electron blocking layer, a hole blocking layer, an electron transport layer, and an electron injection layer. Respective film layers of the organic light-emitting functional layer may be prepared by an evaporation process, and an FMM or an open mask may be used to define the pattern of respective film layers during evaporation. The common electrode layer may cover the organic light-emitting functional layer in the display area. In this way, the pixel electrode and the common electrode layer, as well as the organic light-emitting functional layer located between the pixel electrode and the common electrode layer form an organic light-emitting diode, and any organic light-emitting diode may serve as a sub-pixel of the display panel.

In some embodiments, the pixel layer may further include a light extraction layer located on a side of the common electrode layer away from the base substrate, so as to enhance the light extraction efficiency of the organic light-emitting diode.

In some embodiments, referring to FIG. 16, the display panel may further include a thin film encapsulation layer TFE. The thin film encapsulation layer is provided on the surface of the pixel layer away from the base substrate, and may include an inorganic encapsulation layer(s) and an organic encapsulation layer(s) that are alternately stacked. Herein, the inorganic encapsulation layer may effectively block moisture and oxygen from the outside, and prevent material degradation caused by water and oxygen intrusion into the organic light-emitting functional layer. Alternatively, an edge of the inorganic encapsulation layer may be located in the peripheral are. The organic encapsulation layer is located between two adjacent inorganic encapsulation layers, so as to realize planarization and weaken the stress between the inorganic encapsulation layers. In some embodiments, an edge of the organic encapsulation layer may be located between an edge of the display area and the edge of the inorganic encapsulation layer. Exemplarily, the thin film encapsulation layer includes a first inorganic encapsulation layer, an organic encapsulation layer and a second inorganic encapsulation layer stacked in sequence on a side of the pixel layer away from the base substrate.

In some embodiments, the display panel may further include a touch functional layer, which is provided on a side of the thin film encapsulation layer away from the base substrate, and is configured to realize touch operation of the display panel.

In some embodiments, the display panel may further include an anti-reflection layer, which may be provided on a side of the thin-film encapsulation layer away from the pixel layer and configured to reduce the reflection of the display panel on ambient light, thereby reducing the impact of ambient light on the display effect. In some embodiments of this disclosure, the anti-reflection layer may include a color filter layer and a black matrix layer that are stacked, so as to reduce the interference of ambient light while avoiding reducing the light transmittance of the display panel. In some other embodiments of this disclosure, the anti-reflection layer may be a polarizer, for example, a patterned coated circular polarizer. Moreover, the anti-reflection layer may be provided on a side of the touch functional layer away from the base substrate.

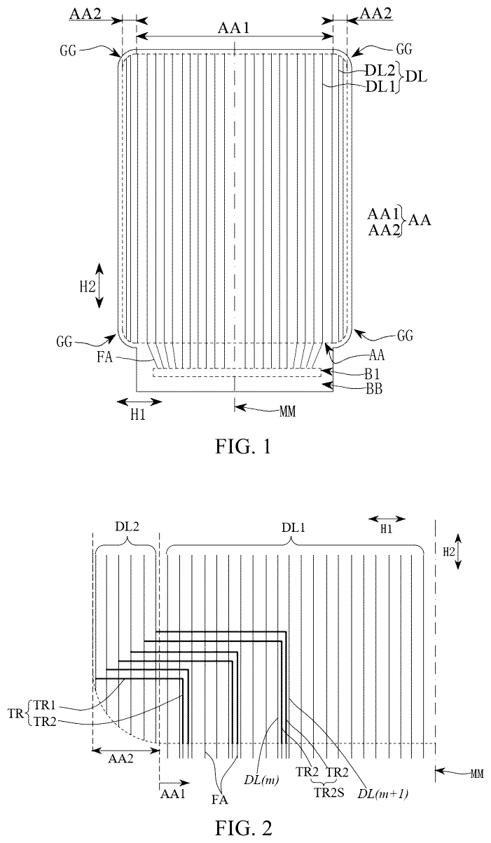

Referring to FIG. 1, viewed from the front view, the display panel may include a display area AA and a peripheral area BB at least partially surrounding the display area AA. In some embodiments, respective sub-pixels may be arranged in the display area AA. The display panel also has a bonding area B1 in the peripheral area BB, and the bonding area is provided with a plurality of pads for bonding a driving chip or a circuit board, so as to realize the driving of the display panel. In this disclosure, an end of the display area AA close to the bonding area B1 may be defined as the lower end, where the lower end of the display area AA is its end in the second direction H2. Respective data lines DL are arranged in sequence along the first direction H1, and are to be electrically connected to the pads in the bonding area B1, so as to receive the driving data signal from the bonding area. Referring to FIG. 1, the display panel may be provided with pad connection lines FA corresponding to the respective data lines DL one by one (only part of the pad connection lines FA are illustrated in FIG. 1). One end of the pad connection line FA extends into the bonding pad so as to be electrically connected to the pad, and the other end is electrically connected to the corresponding data line DL. In this way, the data line DL is electrically connected to the pad in the bonding area B1 through the corresponding pad connection line FA.

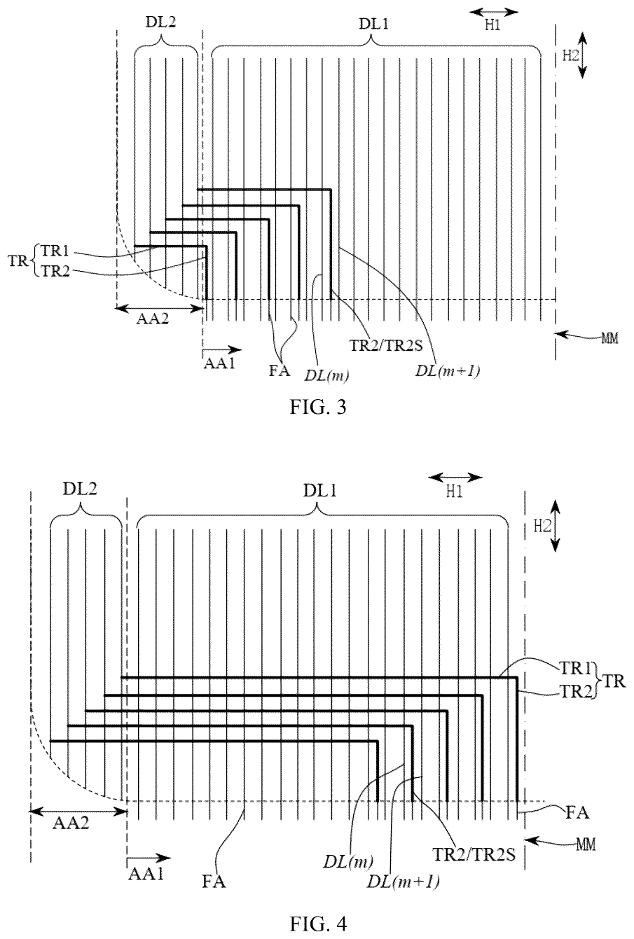

In this disclosure, referring to FIG. 1, along the first direction H1, the display area AA may include a first display area AA1 and two second display areas AA2 respectively located on both sides of the first display area AA1. The data lines DL include a first data line(s) DL1 located in the first display area AA1 and a second data line(s) DL2 located in the second display area AA2. Referring to FIG. 2-FIG. 4, the display panel further includes transition lines TR corresponding to respective second data lines DL2 one by one. One end of the transition line TR is connected to the corresponding second data line DL2, and the other end extends from the first display area AA1 and is electrically connected to the pad connection line FA. In other words, the second data lines DL2 are connected with the transition lines TR, and these transition lines TR extend from the first display area AA1 to the display area AA, and are electrically connected to the bonding area through the pad connection lines FA. In this way, the second data line DL2 does not need to extend from the second display area AA2 to the display area AA and to the bonding area, thereby saving the wiring space at the lower end of the peripheral area BB and, thus, reducing the bezel of the display panel. In this way, according to this disclosure, the data lines DL far away from the central axis MM of the display area AA (i.e., the data lines DL located at outer region of the display area AA) can be transitioned and connected to a region close to the inner side of the display area AA, and electrically connected to the bonding area from a region close to the central axis MM of the display area AA, thereby reducing the wiring space of the pad connection line FA, so that the display panel can have an ultra-narrow lower bezel.

Exemplarily, the second transition line is electrically connected to the pad through a corresponding pad connection line; and the first data line is electrically connected to the pad through a corresponding pad connection line.

In this disclosure, the central axis MM of the display area AA extends along the second direction H2, the number of columns of sub-pixels on both sides of the central axis MM may be the same, and the widths of the display area on both sides thereof are basically the same. Accordingly, the display AA can be regarded as being arranged symmetrically with respect to the central axis MM. For the convenience of expression, in the first direction H1, a side close to the central axis MM of the display area AA may be defined as the inner side, and a side away from the central axis MM of the display area AA may be defined as the outer side. In other words, among two adjacent data lines DL, the outer data line DL is farther away from the central axis MM of the display area AA.

In some embodiments, respective transition lines TR are arranged symmetrically with respect to the central axis MM. In this way, it is beneficial to the design, manufacture and driving of the display panel.

In some embodiments, referring to FIG. 2, the vertex angle of the display panel near the bonding area (i.e., the lower vertex angle) may be a non-right angle, for example, an arc-shaped angle, especially a rounded angle. In such embodiments, respective columns of pixel driving circuits corresponding to the arc-shaped vertex angle may be located in the second display area AA2. In other words, in the first direction H1, the distribution range of the arc-shaped vertex angle falls within the distribution range of the second display area AA2. In this way, the display panel of this disclosure has the lower rounded corners and an ultra-narrow lower bezel, which can realize a large-angle bending function of four sides, and can improve the wrinkle problem during module bonding. Moreover, the arc-shaped vertex angle may be an ultra-narrow rounded corner.

Exemplarily, in the first direction H1, the distribution range of the arc-shaped vertex angle coincides with the distribution range of the second display area AA2. In this way, the data lines DL connected to the respective columns of driving circuits corresponding to the arc-shaped vertex angle may be transitioned and connected to the first display area AA1 through the transition lines TR.

In some embodiments of this disclosure, the display panel may be a flexible display panel. In this way, the flexible display panel can be bent at a large angle at the vertex corner, and wrinkles that may occur when the display panel is attached can be reduced or eliminated, thereby further improving the yield rate of the display device based on the display panel. In such embodiments, by connecting the corresponding data lines DL at the vertex corner to the first display area AA1, ultra-narrow bottom rounded corners and ultra-narrow bottom bezel can be realized for the display panel, thereby further improving the screen-to-body ratio of the display device.

In some embodiments of this disclosure, the vertex angle of the display panel away from the bonding area (i.e., the upper vertex angle) may also be a non-right angle, for example, an arc-shaped angle, especially a rounded angle. Exemplarily, in some embodiments of this disclosure, referring to FIG. 1, the four corners GG of the display panel are all rounded.

In some embodiments, referring to FIG. 2 to FIG. 4, the transition lines TR may include a first transition line(s) TR1 extending along the first direction H1 and a second transition line(s) TR2 extending along the second direction H2. In some embodiments, at least one second transition line TR2 is located between two adjacent first data lines DL1. Moreover, the first data line DL1 may directly extend out of the display area AA and be electrically connected to a pad connection line FA corresponding to the first data line DL1. In this way, according to this disclosure, it is equivalent to interspersing part of the pad connection lines corresponding to the second data lines DL2 between the pad connection lines corresponding to the first data lines DL1. The driving data signal can be adaptively adjusted by the driver of the display device according to the first data lines DL1 and the second transition lines TR2 in the display panel, so as to drive the display panel.

In some embodiments, among two adjacent second data lines DL2, the second transition line TR2, among the transition lines TR, corresponding to the outer second data line DL2 is located on the outer side of the second transition line TR2, among the transition lines TR, corresponding to the inner second data line DL2. In other words, the closer the second data line DL2 is to the outer side, the closer the second transition line TR2 of the second data line DL2 is to the outer side. In this way, the difference in the lengths of the transition lines TR connected to the respective second data lines DL2 is small, so the impact difference on the impedance of the respective second data lines DL2 is small, which is beneficial to making compensation for the driving data signal on the respective second data lines DL2.

Correspondingly, among two adjacent second data lines DL2, the first transition line TR1, among the transition lines TR, corresponding to the outer second data line DL2 is located on the side, close to the pad connection line FA, of the first transition line TR1, among the transition lines TR, corresponding to the inner second data line DL2. That is, the closer the second data line DL2 is to the outer side, the closer the first transition line TR1, connected to the second data line DL2, is to the bonding end.

Alternatively, in other embodiments of this disclosure, the transition lines may also be arranged in other ways. Exemplarily, among two adjacent second data lines, the second transition line, among the transition lines, corresponding to the outer second data line is located on the inner side of the second transition line, among the transition lines, corresponding to the inner second data line. Among the two adjacent second data lines, the first transition line, among the transition lines, corresponding to the inner second data line is located on the lower end side of the first transition line, among the transition lines, corresponding to the outer second data line.

In some embodiments, the lengths of the respective transition lines TR may be substantially the same, for example, the length of the longest transition line TR is between 1.0 and 1.2 times the length of the shortest transition line TR. In this way, the difference in the lengths of respective transition lines TR is small, and the influence on the driving data signals loaded on the second data lines DL2 is small, which is beneficial to making compensation for the driving data signals on the second data lines DL2. In this disclosure, the lengths of the first transition line TR1 and the second transition line TR2 may be adjusted by adjusting the positions of the first transition line TR1 and the second transition line TR2, thereby adjusting the lengths of the transition lines TR.

In this disclosure, the second transition lines may be provided on the same conductive layer, or may be provided on different conductive layers. For example, the second transition lines include two different types: the first sub-line(s) and the second sub-line(s), and the first sub-line and the second sub-line are provided on different conductive layers. In at least some areas, the first sub-lines and the second sub-lines are arranged alternately, so as to reduce the wiring space of the second transition lines.

In some embodiments of this disclosure, the data lines may be provided on the source-drain metal layer, for example, may be provided on the second source-drain metal layer. The transition lines TR may be provided on the source-drain metal layer. For example, the first transition line TR1 is provided on the first source-drain metal layer and the second transition line TR2 is provided on the second source-drain metal layer. For another example, the first transition line TR1 is provided on the first source-drain metal layer, part of the second transition lines TR2 is provided on the first source-drain metal layer, and the rest of the second transition lines TR2 is provided on the second source-drain metal layer. For another example, the source-drain metal layer includes a first source-drain metal layer, a second source-drain metal layer, and a third source-drain metal layer stacked on one side of the transistor layer in sequence, and the first transition line TR1 and the second transition line TR2 are both provided on the third source-drain metal layer.

In this disclosure, the driving circuit layer is provided with thin film transistors of the driving circuit, and the transition lines TR do not overlap with the thin film transistors. Further, the positions and gaps of respective thin film transistors may be adjusted according to needs, so as to reserve space for laying the transition lines TR.

In this disclosure, when it is described that two structures overlap, it means that the two structures are in different film layers, and the orthographic projections of the two structures on the base substrate are at least partially overlapped. When it is described that two structures do not overlap, it means that the two structures are in different film layers, and the orthographic projections of the two structures on the base substrate have no overlapping area.

In this disclosure, referring to FIG. 8, the display panel may include driving circuit regions PDCA provided in one-to-one correspondence with respective driving circuits. In some embodiments, most or all transistors of a driving circuit may be located in a corresponding driving circuit region PDCA of the driving circuit, and a small number of transistors of the driving circuit may be located in an adjacent driving circuit region PDCA, so as to facilitate layout and reuse of signal lines. The transition lines TR do not overlap with the driving circuit regions PDCA.

In some embodiments, the driving circuit layer may include a transistor layer (including a semiconductor layer and a gate layer) and a source-drain metal layer (e.g., a first source-drain metal layer and a second source-drain metal layer). The source-drain metal layer is provided with lines and conductive structure, where the conductive structures are configured to electrically connect the transistors and the lines. Accordingly, a driving circuit region PDCA corresponding to a driving circuit may be defined according to the distribution range of conductive structures of the driving circuit. In some embodiments of this disclosure, the driving circuit region PDCA is a rectangular region, where long sides of the rectangular region extend along the column direction, and short sides thereof extend along the first direction. Respective conductive structures of a driving circuit are located in the driving circuit region PDCA corresponding to the driving circuit.

In some embodiments, the driving circuit has a storage capacitor, a driving transistor, and a data writing transistor connected to the data line DL, where the storage capacitor, the driving transistor, and the data writing transistor of the driving circuit are all located in the driving circuit region PDCA corresponding to the driving circuit.

In some embodiments, among two driving circuits adjacent in the second direction H2, at least one thin film transistor of the driving circuit in the upper row is located in the driving circuit region PDCA corresponding to the driving circuit in the lower row; and the remaining thin film transistors of the driving circuit in the upper row are located in the driving circuit region PDCA corresponding to the driving circuit. As an example, the driving circuit is provided with an electrode reset transistor for resetting the pixel electrode; and the electrode reset transistor of the driving circuit may be located in the driving circuit region PDCA corresponding to the driving circuit in the lower row. Correspondingly, for the driving circuit region PDCA not located at the edge of the display area AA, an electrode reset transistor of the driving circuit in the upper row is also arranged inside it.

In some embodiments, referring to FIG. 8, the driving circuit layer includes driving circuit islands PDCC distributed in an array, and any driving circuit island PDCC includes one or more driving circuit regions PDCA in one-to-one correspondence with respective driving circuits. At least some transistors of a driving circuit are provided in the corresponding driving circuit region PDCA. Referring to FIG. 8, respective driving circuit regions PDCA in a driving circuit island PDCC are arranged adjacent to each other in sequence, and there is a gap between the driving circuit islands PDCC. The transition lines TR are provided in the gap between the driving circuit islands PDCC.

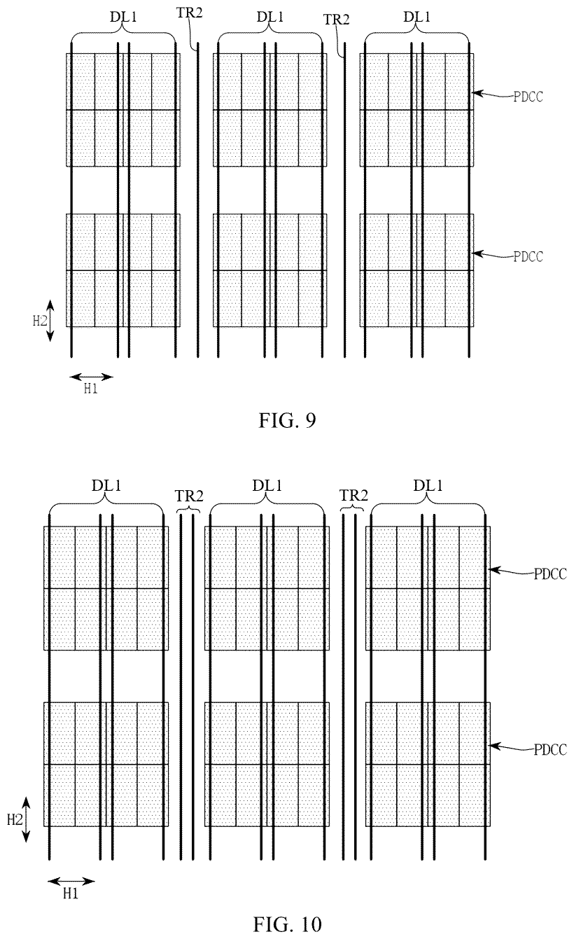

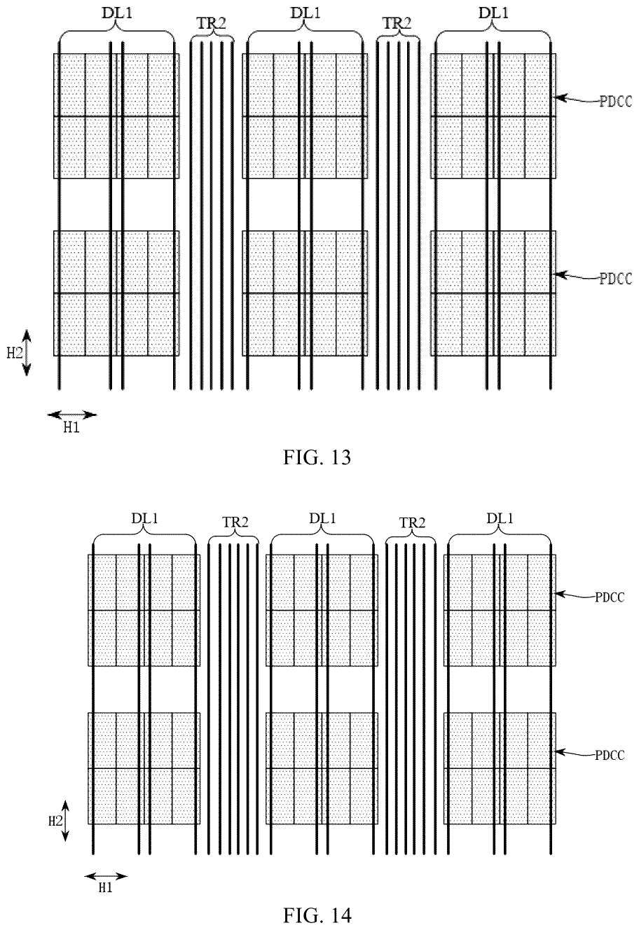

In some embodiments of this disclosure, the driving circuit islands PDCC may be arranged in a plurality of driving circuit island PDCC rows, where each driving circuit island PDCC row includes a plurality of driving circuit islands PDCC arranged along the first direction H1, and respective driving circuit island PDCC rows are sequentially arranged along the second direction. A row gap CC is provided between two adjacent driving circuit island PDCC rows. The driving circuit islands PDCC may also be arranged into a plurality of driving circuit island PDCC columns, where each driving circuit island PDCC column includes a plurality of driving circuit island PDCC arranged along the second direction H2, and respective driving circuit island PDCC columns are sequentially arranged along the first direction arranged. A column gap DD is provided between two adjacent driving circuit island PDCC columns. Referring to FIG. 9 to FIG. 15, the transition lines TR are provided in the gaps (e.g., the row gap CC or the column gap DD shown in FIG. 8) between the driving circuit islands PDCC.

Referring to FIG. 8, there may be no gap or a small gap between adjacent driving circuit regions PDCA in the driving circuit island PDCC. In this way, the respective driving circuit regions PDCA in the driving circuit island PDCC can be arranged compactly, so as to facilitate the formation of larger gaps between the driving circuit islands PDCC, and further facilitate the layout of the transition lines TR. It can be understood that when some thin film transistors of a driving circuit are not located in a driving circuit region PDCA corresponding to the driving circuit, these thin film transistors may be located in another driving circuit region PDCA in the same driving circuit island PDCC, or may be located in a driving circuit region PDCA in an adjacent driving circuit island PDCC. This disclosure is not limited thereto.

In some embodiments, the driving circuits are arranged into a plurality of driving circuit groups, where each driving circuit group includes two driving circuits that are adjacent and mirrored with respect to the first direction H1. Herein, two driving circuit regions PDCA respectively corresponding to the two driving circuits in a driving circuit group are adjacently arranged and located in a same driving circuit island PDCC. Alternatively, in some other embodiments of this disclosure, the adjacent driving circuits may not adopt the mirrored arrangement, and the patterns of two adjacent driving circuits in the same row may be basically the same.

In some embodiments, the driving circuit regions PDCA in the driving circuit island PDCC are arranged in multiple rows and multiple columns, so that the driving circuit island PDCC have a relatively large area, thereby making the gap between the driving circuit islands PDCC relatively large, which is beneficial to arranging transition lines TR in the gap between the driving circuit islands PDCC. In some embodiments of this disclosure, the driving circuit regions PDCA in the driving circuit island PDCC are arranged in two rows and four columns.

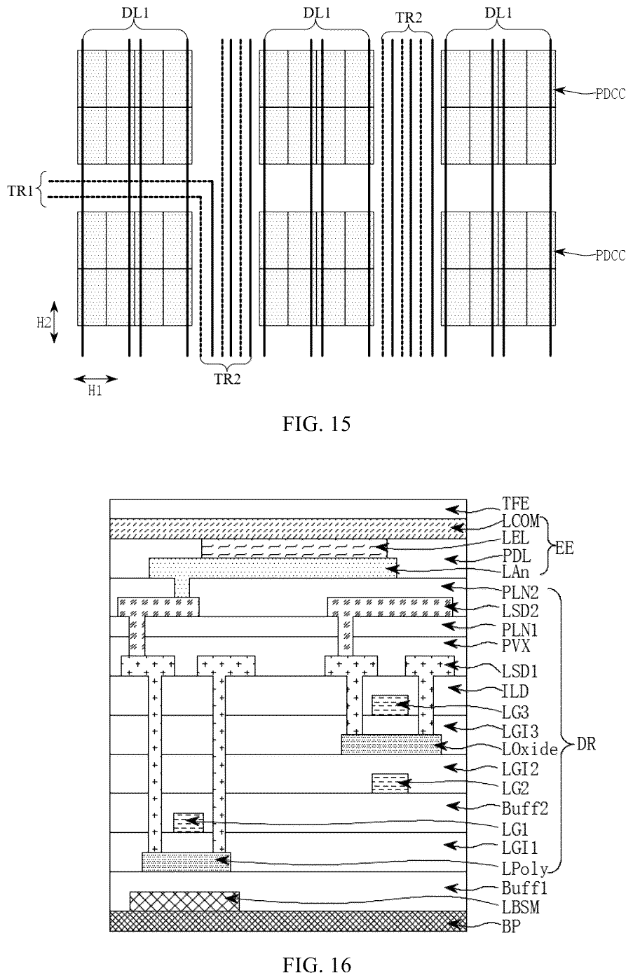

The number of transition lines TR provided in a gap between the driving circuit islands PDCC, on the one hand, may be adjusted according to the actual wiring requirements and, on the other hand, depends on the size of the gap, the width of the transition line TR, the spacing between transition lines TR, and the film layer(s) for providing the transition line TR. In this disclosure, the smaller the gap between the driving circuit islands PDCC is, the smaller the number of transition lines TR may be provided in the gap. In this disclosure, different film layers are used to arrange the transition lines TR, which helps to increase the number of transition lines TR. For example, the transition lines TR may be arranged alternately on adjacent conductive film layers, so as to increase the wiring density of the transition lines TR. Exemplarily, in FIG. 15, the wirings on the first source-drain metal layer LSD1 are indicated by dotted lines, and the wirings on the second source-drain metal layer LSD2 are indicated by solid lines. In some embodiments, adjacent second transition lines TR2 are arranged alternately on the first source-drain metal layer LSD1 and the second source-drain metal layer LSD2, so as to increase the wiring density of the second transition lines TR2. Referring to FIG. 9 to FIG. 15, the number of the second transition lines TR2 between the driving circuit island PDCC columns may be determined according to technological requirements and may be, for example, any number of 1 to 6.

In some embodiments, the area of the driving circuit region PDCA may be made as small as possible, for example, reaching or approaching the limit allowed by the corresponding process. In this way, the area ratio of the driving circuit regions PDCA in the display area AA can be reduced, and the area ratio of the gaps between the driving circuit islands PDCC can be increased, so that the layout of the transition lines TR can be more flexible. In this disclosure, the greater the PPI (Pixels Per Inch, indicating the pixel density) of the display panel, the greater the distribution density of the driving circuit regions PDCA, the smaller the allowable gap between the driving circuit islands PDCC, and the more likely the wiring numbers of the transition line TRs are limited. In some cases of high pixel density (e.g., PPI is not less than 490) or large rounded corners (e.g., the number of second data lines DL2 in a second display area AA2 is not less than 350), this disclosure may be implemented by adding a new source-drain metal layer (e.g., the third source-drain metal layer) to providing the transition lines TR, or by only connecting the second data lines DL2 to the pad connection lines FA through the transition lines TR, so as to reduce the lower bezel of the display panel.

In some embodiments, the source-drain metal layer includes a first source-drain metal layer LSD1 and a second source-drain metal layer LSD2 stacked on the side of the transistor layer away from the base substrate in sequence. The data lines DL are arranged on the second source-drain metal layer LSD2. The transition lines TR include a first transition line(s) TR1 extending along the first direction H1 and a second transition line(s) TR2 extending along the second direction H2. The first transition line(s) TR1 is provided on the first source-drain metal layer LSD1; and the second transition line(s) TR2 is provided on the second source-drain metal layer LSD2 and/or the first source-drain metal layer LSD1. In such embodiments, if the gap between the driving circuit islands PDCC is sufficient to arrange the transition lines TR, the existing first source-drain metal layer LSD1 and second source-drain metal layer LSD2 can be directly used to lay the transition lines TR, so as to avoid increasing the thickness and cost of the display panel by adding additional metal layers. In some embodiments of this disclosure, the second transition lines TR2 may be all provided on the second source-drain metal layer LSD2. In some other embodiments of this disclosure, the second transition lines TR2 may be partially provided on the first source-drain metal layer LSD1 and partially provided on the second source-drain metal layer LSD2. For example, the second transition lines TR2 are alternately provided on the first source-drain metal layer LSD1 and the second source-drain metal layer LSD2.

In some embodiments of this disclosure, the driving circuit layer further includes an electrode initialization voltage line(s) extending along the first direction H1, which is used for loading an electrode reset voltage for resetting the pixel electrode(s). The electrode initialization voltage line includes a first initialization line(s) Vinit2L1 and a second initialization line(s) Vinit2L2 that are alternately connected, where the first initialization line Vinit2L1 is provided on the gate layer, the second initialization line Vinit2L2 is provided on the first source-drain metal layer LSD1, and the first initialization line Vinit2L1 and the second initialization line Vinit2L2 are connected through via holes. In some embodiments, part of the second transition lines TR2 is provided on the first source-drain metal layer LSD1, and the second transition lines TR2 overlap with the first initialization line Vinit2L1 but does not overlap with the second initialization line Vinit2L2. In this way, the electrode initialization voltage line may avoid the second transition lines TR2 located on the first source-drain metal layer LSD1 through the first initialization line Vinit2L1. Further, the first initialization line Vinit2L1 spans the gap between the driving circuit islands PDCC along the first direction. Alternatively, in some other embodiments of this disclosure, the electrode initialization voltage line may be provided on the first source-drain metal layer LSD1, while the second transition lines TR2 may be provided on a conductive film layer above the first source-drain metal layer LSD1 (away from the base substrate BP) and, for example, may be provided on the second source-drain metal layer LSD2.

In some other embodiments, the source-drain metal layer includes a first source-drain metal layer LSD1, a second source-drain metal layer LSD2 and a third source-drain metal layer LSD3 sequentially stacked on the side of the transistor layer away from the base substrate. The data lines DL are provided on the second source-drain metal layer LSD2, and the transition lines TR are provided on the third source-drain metal layer LSD3. In this way, for some cases where the first source-drain metal layer LSD1 and the second source-drain metal layer LSD2 cannot provide enough space to lay out the transition lines TR, for example, for some cases where the gap between the driving circuit islands PDCC is not sufficient to provide enough transition lines TR due to high resolution (e.g., PPI is not less than 490), or for some cases where the transition lines TR are too many (e.g., the number of second data lines DL2 in a second display area AA2 is not less than 350) due to a relatively large rounded corner, the transition lines TR may be arranged on the third source-drain metal layer LSD3 of the display panel according to this disclosure, so as to connect the second data lines DL2 to the corresponding pad connection lines FA through the transition lines TR.

In some embodiments of this disclosure, the end of the first data line DL1 close to the bonding area is directly connected to a corresponding pad connection line FA. The second data line DL2 is connected to the pad connection line FA through the transition line TR. In this way, too many transition lines TR can be avoided on the display panel, which facilitates the layout of the transition lines TR, and is especially suitable for high-resolution display panels and display panels with large rounded corners.

In some other embodiments of this disclosure, at least part of the first data lines DL1 may also be transitioned and connected, through the transition lines TR, to the pad connection lines FA corresponding to the first data lines DL1. In other words, the display panel further includes transition lines TR electrically connected to at least part of the first data lines DL1 in one-to-one correspondence. In this way, the transition lines TR are electrically connected to the second data lines DL2 and the at least part of the first data lines DL1 in one-to-one correspondence. The transition lines TR corresponding to respective data lines DL are electrically connected to the pad connection lines FA corresponding to the data lines DL. Alternatively, if a first data line DL1 does not have a corresponding transition line TR, then the first data line DL1 may be directly and electrically connected to the pad connection line FA. When the source-drain metal layer has enough space to lay out enough transition lines TR, for example, when the resolution of the display panel is low (e.g., PPI is less than 410) or the LSD3 is provided, the wiring sequence and position of the pad connection lines FA can be further adjusted, which is beneficial to the preparation and optimization of the display panel. In some embodiments of this disclosure, the arrangement sequence of the pad connection lines FA corresponding to respective data lines DL is consistent with the arrangement sequence of respective data lines DL. In this way, the structure of the external driving circuit can be simplified, for example, the structure of the driving chip can be simplified.

In this disclosure, the first display area AA1 may include two arrangement areas respectively located on both sides of the central axis MM, where the central axis MM extends along the second direction H2. In some embodiments of this disclosure, the transition lines TR and the first data lines DL1 are arranged symmetrically with respect to the central axis MM.

In this disclosure, referring to FIG. 2, respective second transition lines TR2 may be arranged into a plurality of second transition line groups TR2S, where respective second transition lines TR2 in any second transition line group TR2S is located between two adjacent driving circuit island PDCC columns (i.e., in the same column gap DD), any two adjacent second transition line groups TR2S are separated by the driving circuit island PDCC column, and any second transition line group TR2S includes one or more second transition lines TR2. Referring to FIG. 2 to FIG. 4, it can be seen that respective second transition lines TR2 in the second transition line group TR2S are located between two adjacent data lines DL, for example, between a data line DL(m) numbered m and a data line DL(m+1) numbered m+1. In some embodiments of this disclosure, the number of the second transition lines TR2 in any second transition line group TR2S is no more than six. In other words, the number of the second transition lines TR2 between two adjacent driving circuit island PDCC columns is no more than six.

In some embodiments of this disclosure, the plurality of second transition lines are arranged into a plurality of second transition line groups, where each of the second transition line groups includes at least two adjacent second transition lines. The plurality of first data lines are arranged into a plurality of first data line groups, where each of the first data line groups includes a plurality of adjacent first data lines. In at least a partial area of the first display area, the first data line groups and the second transition line groups are alternately arranged one by one.

In some embodiments of this disclosure, in at least one arrangement area, the numbers of the second transition lines TR2 in respective second transition line groups TR2S are the same. In some other embodiments of this disclosure, in at least one arrangement area, one of the second transition line groups TR2S has a smaller number of second transition lines TR2, and the remaining second transition line groups TR2S have more and the same number of second transition lines TR2.

For example, on the same side of the central axis MM, the outermost or innermost second transition line group TR2S has fewer second transition lines TR2, and the remaining second transition line groups TR2S contain more and the same number of second transition lines TR2. Alternatively, in other embodiments of this disclosure, the numbers of second transition lines TR2 in respective second transition line groups TR2S may be independently set according to needs, and the numbers of second transition lines TR2 in any two second transition line groups TR2S may be the same or different.

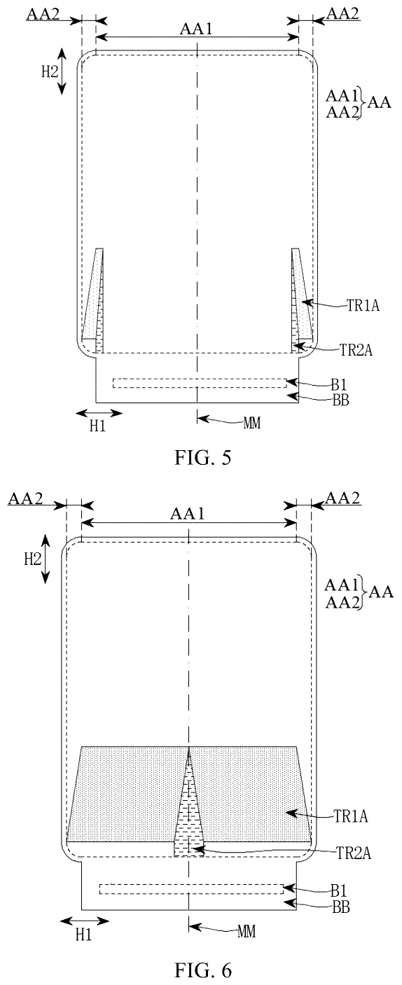

In this disclosure, in at least one arrangement area, referring to FIG. 5 to FIG. 7, an area where the respective second transition line groups TR2S are distributed may be defined as a second transition area TR2A.

According to some embodiments, in the second transition area TR2A and along the first direction H1, the driving circuit island PDCC columns and the second transition line groups TR2S are sequentially arranged at intervals. In this way, the size of the second transition are TR2A in the first direction H1 can be reduced. The start position or end position of the second transition line group TR2S can be adjusted as required.

In some embodiments of this disclosure, referring to FIG. 5, the starting position of the second transition area TR2A (i.e., the starting position where the second transition line groups TR2S are arranged from the outside to the inside) may be close to the outer side of the first display area AA1. For example, in at least one arrangement area, the outermost second transition line group TR2S is arranged adjacent to the outermost driving circuit island PDCC column. As an example, the outermost second transition line group TR2S is located on the outer side of the outermost first data line DL1.

In some other embodiments of this disclosure, referring to FIG. 6, the end position of the second transition area TR2A (i.e., the end position where the second transition line groups TR2S are arranged from the outside to the inside) may be close to the central axis MM of the first display area AA1. For example, in at least one arrangement area, the innermost second transition line group TR2S is arranged adjacent to the innermost driving circuit island PDCC column.

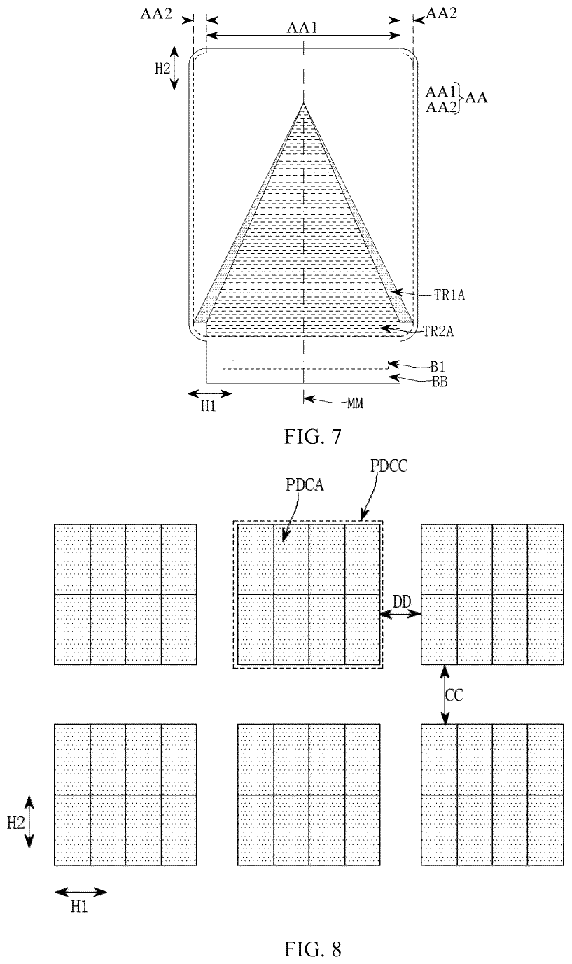

In some other embodiments of this disclosure, referring to FIG. 7, in at least one arrangement area, the second transition area TR2A may be distributed throughout the arrangement area. In other words, in at least one arrangement area, the second transition line groups TR2S may be uniformly or non-uniformly distributed in the arrangement area along the first direction H1. As an example, the respective second transition line groups TR2S are distributed in the first display area AA1 along the first direction H1.

In this disclosure, respective first transition lines TR1 may be arranged into a plurality of first transition line groups TR1S, where respective first transition lines TR1 in any one of the first transition line groups TR1S are located between two adjacent driving circuit island PDCC rows (e.g., located in the same row gap CC), and located in the same arrangement area. Any two adjacent first transition line groups TR1S are separated by the driving circuit island PDCC row; and any first transition line group TR1S includes one or more first transition lines TR1.

In some embodiments of this disclosure, the number of the first transition lines TR1 in any one of the first transition line groups TR1S is no more than three. In other words, the number of the first transition lines TR1 between two adjacent driving circuit island PDCC rows is no more than three.

In some embodiments of this disclosure, in at least one arrangement area, the numbers of first transition lines TR1 in respective first transition line groups TR1S are the same. In some other embodiments of this disclosure, in at least one arrangement area, one of the first transition line groups TR1S has a smaller number of first transition lines TR1, and the remaining first transition line groups TR1S have more and the same number of first transition lines TR1. For example, on the same side of the central axis MM, the first transition line group TR1S closest to the pad connection line FA or farthest from the pad connection line FA has fewer first transition lines TR1, and the remaining first transition line groups TR1S include more and the same number of first transition lines TR1. Alternatively, in other embodiments of this disclosure, the numbers of first transition lines TR1 in respective first transition line groups TR1S may be independently set as required, and the numbers of first transition lines TR1 in any two first transition line groups TR1S may be the same or different.

In this disclosure, in at least one arrangement area, referring to FIG. 5 to FIG. 7, the area where the respective first transition line groups TR1S are distributed may be defined as the first transition area TR1A. According to some embodiments, in the first transition area TR1A and along the second direction H2, the driving circuit island PDCC rows and the first transition line groups TR1S are sequentially arranged at intervals. In this way, the size of the first transition area in the second direction H2 can be reduced.

As follows, a specific structure of a display panel is taken as an example in order to further explain and illustrate the structure and principle of the display panel according to this disclosure. It may be understood that, in the display panel of this disclosure, the structure of the driving circuit may be other than this example, as long as the driving of the sub-pixels can be realized.

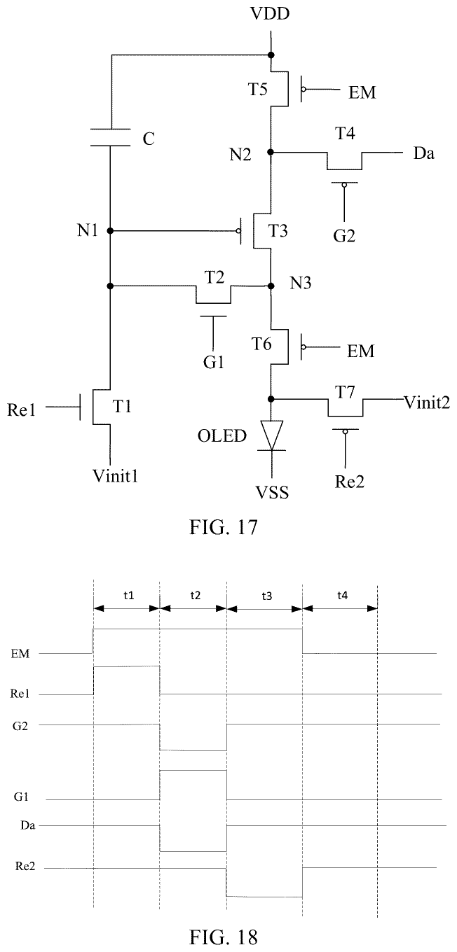

In the display panel of this example, referring to FIG. 17, the driving circuit may include a capacitor reset transistor T1, a threshold compensation transistor T2, a driving transistor T3, a data writing transistor T4, a first light emission control transistor T5, a second light emission control transistor T6 and an electrode reset transistor T7, and may include a storage capacitor C.

In some embodiments, the capacitor reset transistor T1 and the threshold compensation transistor T2 are N-type thin film transistors, such as metal oxide thin film transistors; and the other transistors TFT are P-type thin film transistors, such as low temperature polysilicon thin film transistors.

Referring to FIG. 17, the source of the capacitor reset transistor T1 is used to load the capacitor reset voltage Vinit1, the gate thereof is used to load the capacitor reset control signal Re1, and the drain thereof is connected to a first node N1. The capacitor reset transistor T1 is used to load the capacitor reset voltage Vinit1 to the first node N1 in response to the capacitor reset control signal Re1. The source of the threshold compensation transistor T2 is electrically connected to a third node N3, the drain thereof is electrically connected to the first node N1, and the gate thereof is used to load the first scanning signal G1. The threshold compensation transistor T2 is configured to be turned on in response to the first scanning signal G1, so as to write the threshold voltage of the driving transistor T3 into the first node N1. The source of the driving transistor T3 is connected to the second node N2, the drain thereof is connected to the third node N3, and the gate thereof is connected to the first node N1. The source of the data writing transistor T4 is used to load the driving data signal Da, the drain thereof is electrically connected to the second node N2, and the gate thereof is used to load the second scanning signal G2. The data writing transistor T4 is used to load the driving data signal Da to the second node N2 in response to the second scanning signal G2. The source of the first light emission control transistor T5 is used to load the power supply voltage VDD, the drain thereof is connected to the second node N2, and the gate thereof is used to load the enable signal EM. The source of the second light emission control transistor T6 is connected to the third node N3, the drain thereof is connected to the sub-pixel (the organic electroluminescent diode OLED is taken as an example in FIG. 17), and the gate thereof is used to load the enable signal EM. The first light emission control transistor T5 and the second light emission control transistor T6 are configured to be turned on in response to the enable signal EM. The source of the electrode reset transistor T7 is used to load the electrode reset voltage Vinit2, the drain thereof is connected to a light-emitting element, and the gate thereof is used to load the electrode reset control signal Re2. The electrode reset transistor T7 is used to load the electrode reset voltage Vinit2 to the light-emitting element in response to the electrode reset control signal Re2. The pixel electrodes of the light-emitting element are electrically connected to the driving circuit, and the common electrodes thereof are used to load a common voltage VSS. One end of the storage capacitor C is connected to the first node N1, and the other end is used to load the power supply voltage VDD.

FIG. 18 shows a schematic diagram illustrating a driving sequence of the driving circuit of this example. In FIG. 18, G1 represents the timing of the first scanning signal G1, G2 represents the timing of the second scanning signal G2, Re1 represents the timing of the capacitor reset control signal Re1, Re2 represents the timing of the electrode reset control signal Re2, EM represents the timing of the enable signal EM, and Da represents the timing of the driving data signal Da.

The pixel driving circuit may work in four phases including a capacitor reset phase t1, a threshold compensation phase t2, an electrode reset phase t3, and a light emitting phase t4.

In the capacitor reset phase t1, the capacitor reset signal Re1 is a high-level signal, the capacitor reset transistor T1 is turned on, and the capacitor reset voltage Vinit1 is loaded to the first node N1. Under the control of the first node N1, the driving transistor T3 is turned on.

In the threshold compensation phase t2, the first scanning signal G1 is a high-level signal, the second scanning signal G2 is a low-level signal, the data writing transistor T4 and the threshold compensation transistor T2 are turned on, the data writing transistor T4 writes the voltage Vdata of the driving data signal Da to the second node N2, and finally the first node N1 is charged to a voltage of Vdata+Vth, where Vth is the threshold voltage of the driving transistor T3.

In the electrode reset phase t3, the electrode reset control signal Re2 is a low-level signal, the electrode reset transistor T7 is turned on, and the electrode reset transistor T7 loads the capacitor reset voltage Vinit2 to the pixel electrode of the light-emitting element.

In the light emitting phase t4, the enable signal EM is a low-level signal, the first light emission control transistor T5 and the second light emission control transistor T6 are turned on, and the driving transistor T3 outputs a driving current under the control of the first node N1, thereby driving the light-emitting element to emit light. According to an output current formula of the driving transistor, I=(μWCox/2L)(Vgs−Vth)², where μ is the carrier mobility, Cox is the gate capacitance per unit area, W is the channel width of the driving transistor, L is the channel length of the driving transistor, Vgs is the gate-source voltage difference of the driving transistor, and Vth is the threshold voltage of the driving transistor. The output current of the driving transistor in the pixel driving circuit according to this disclosure is I=(μWCox/2L)(Vdata+Vth−Vdd−Vth)². The pixel driving circuit can avoid the influence of the threshold of the driving transistor on its output current.

Referring to FIG. 16, the display panel of this example may include a base substrate BP, a light-shielding layer LBSM, a first insulating buffer layer Buff1, a low-temperature polysilicon semiconductor layer LPoly, a first gate insulating layer LGI1, a first gate layer LG1, a second insulating buffer layer Buff2 (e.g., an inorganic layer such as silicon nitride, silicon oxide and the like), a second gate layer LG2, a second gate insulating layer LGI2, a metal oxide semiconductor layer LOxide, a third gate insulating layer LGI3, a third gate layer LG3, an interlayer dielectric layer ILD, a first source-drain metal layer LSD1, a passivation layer PVX, a first planarization layer PLN1, a second source-drain metal layer LSD2, a second planarization layer PLN2, a pixel electrode layer LAn, a pixel definition layer PDL, an organic light-emitting functional layer LEL, a common electrode layer LCOM and a thin film encapsulation layer TFE stacked in sequence.

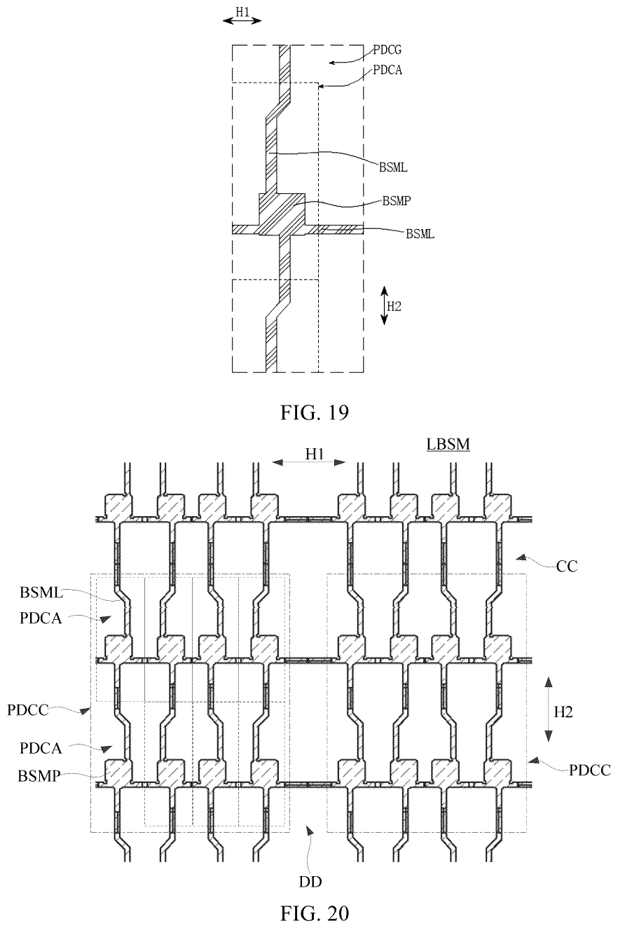

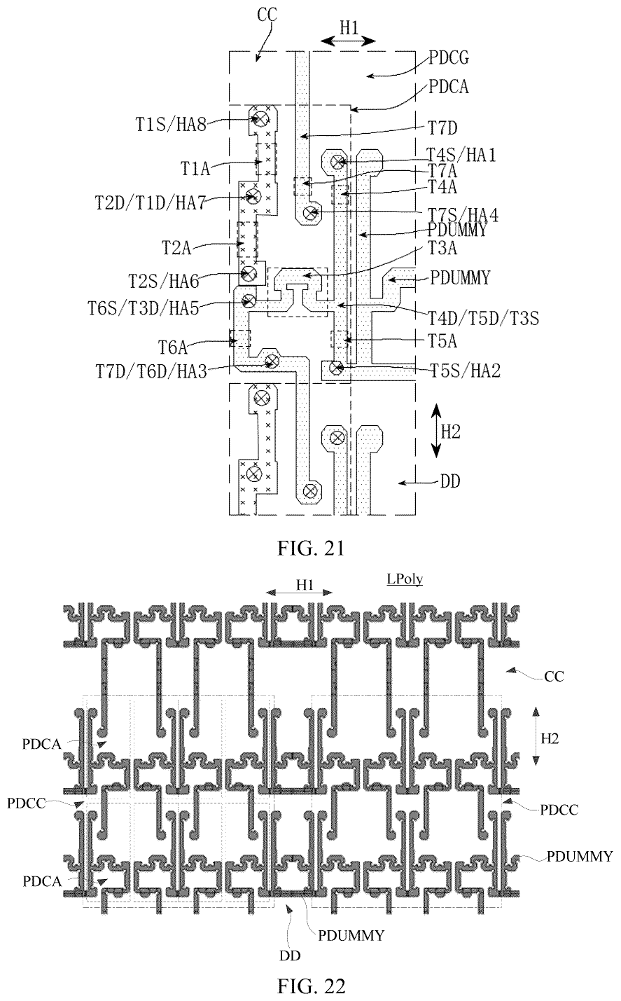

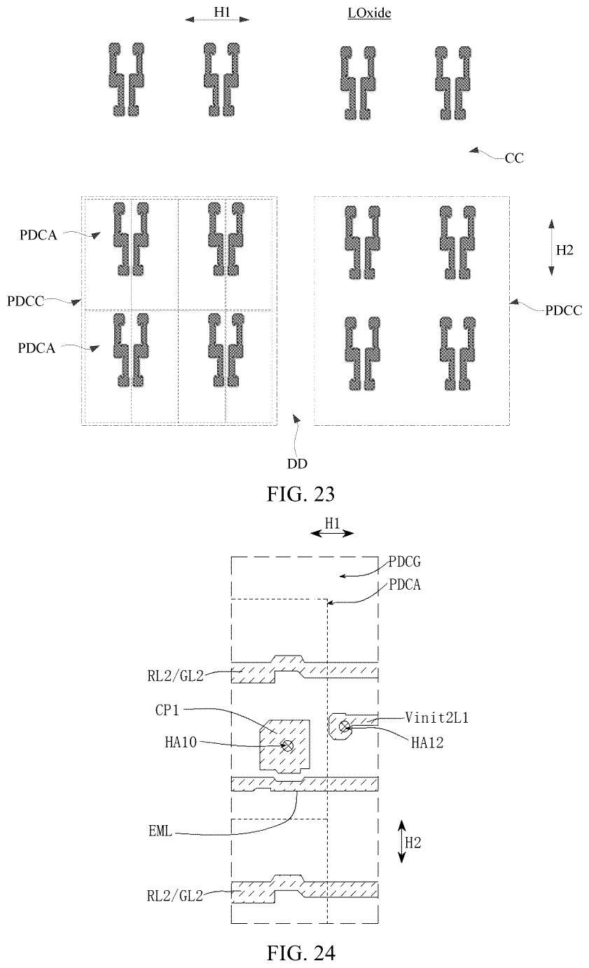

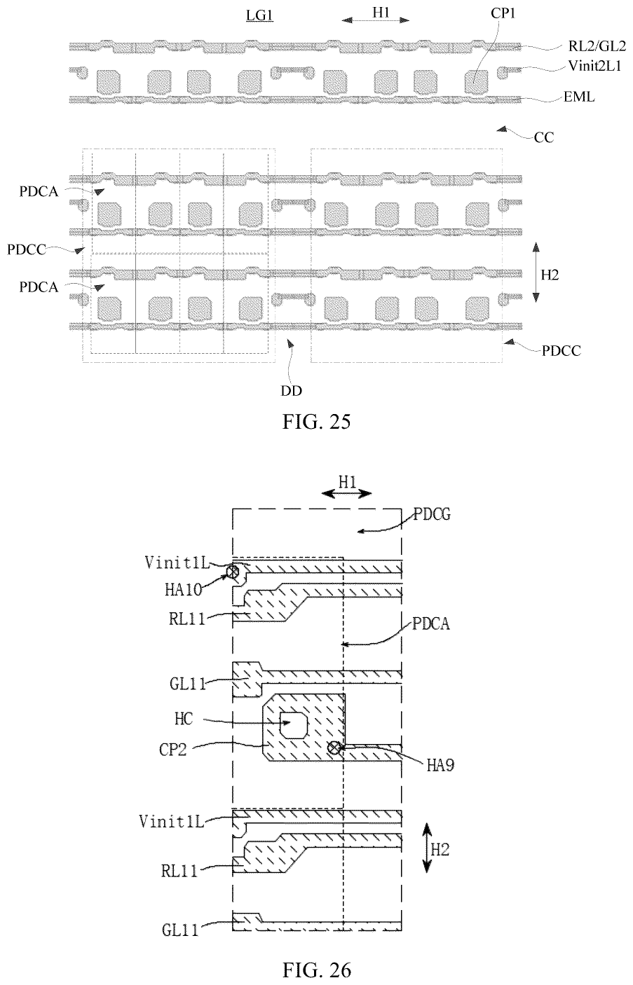

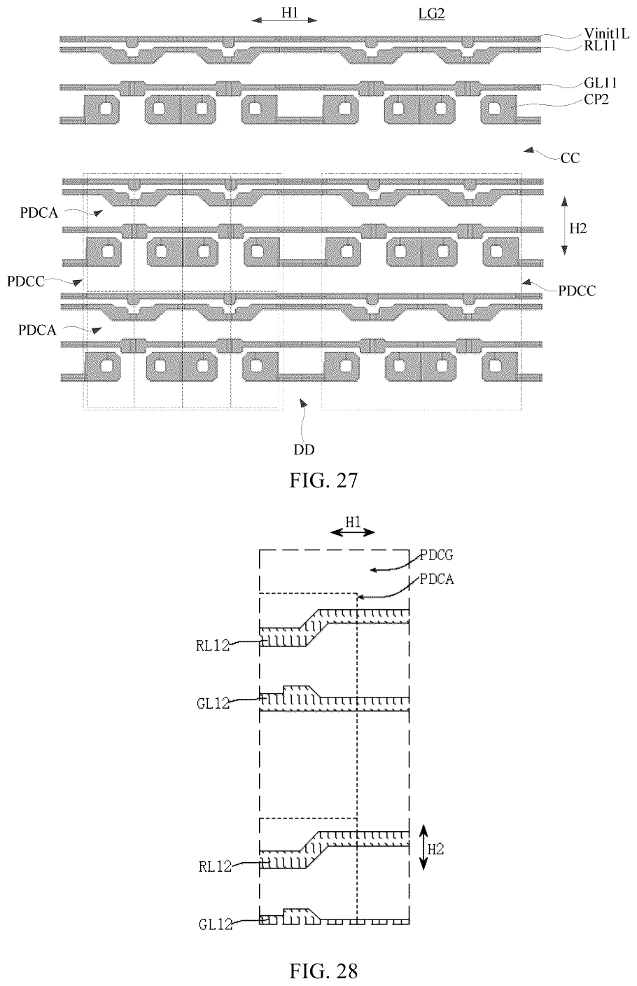

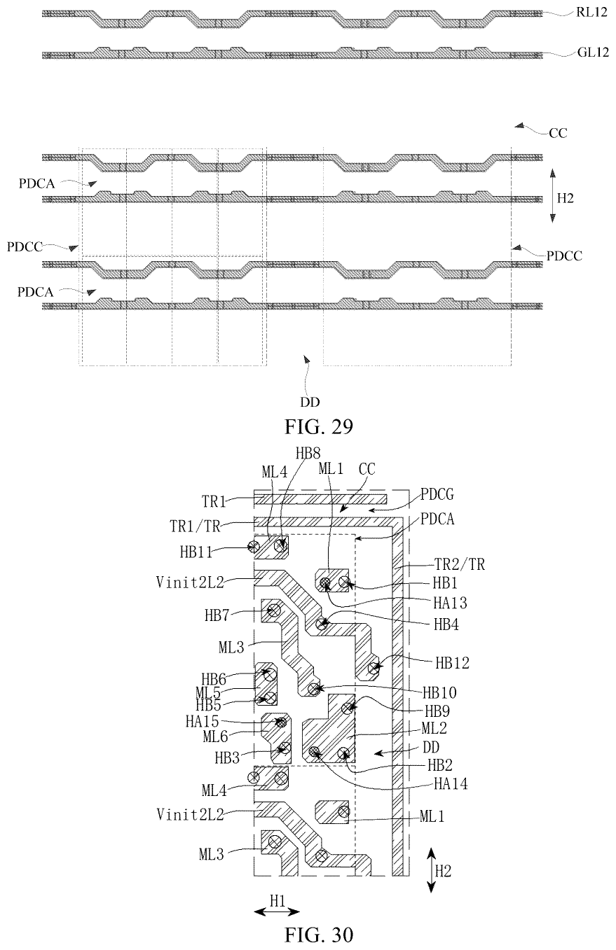

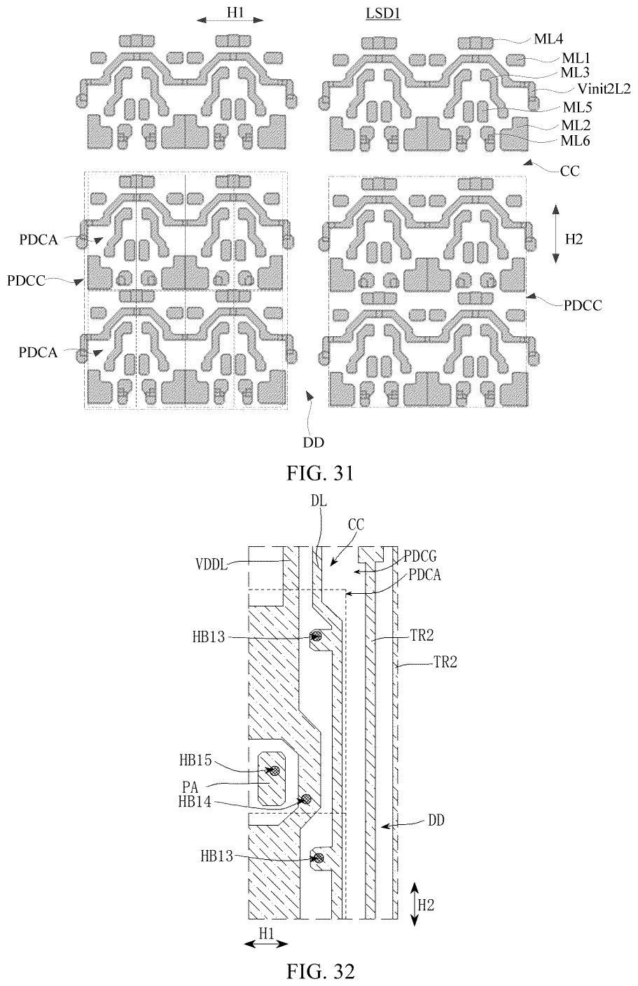

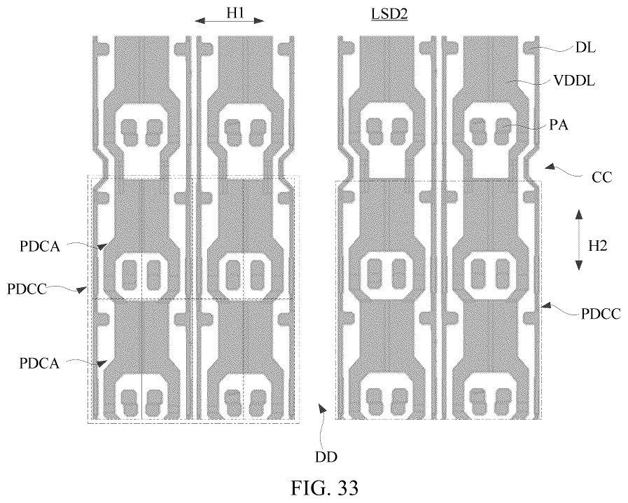

FIG. 19 shows a schematic structural view of the light shielding layer LBSM in a driving circuit region PDCA and its surrounding range (covering at least one driving circuit region PDCA); FIG. 20 shows a schematic structural view of the light shielding layer LBSM in a partial area of the display area (covering at least two driving circuit islands PDCC); FIG. 21 shows a schematic structural view of the low-temperature polysilicon semiconductor layer LPoly and the metal oxide semiconductor layer LOxide in a driving circuit region PDCA and its surrounding range (covering at least one driving circuit region PDCA); FIG. 22 shows a schematic structural view of the low-temperature polysilicon semiconductor layer LPoly in a partial area of the display area (covering at least two driving circuit islands PDCC); FIG. 23 shows a schematic structural view of the metal oxide semiconductor layer LOxide in a partial area of the display area (covering at least two driving circuit islands PDCC); FIG. 24 shows a schematic structural view of the first gate layer LG1 in a driving circuit region PDCA and its surrounding range (covering at least one driving circuit region PDCA); FIG. 25 shows a schematic structural view of the first gate layer LG1 in a partial area of the display area (covering at least two driving circuit islands PDCC); FIG. 26 shows a schematic structural view of the second gate layer LG2 in a driving circuit region PDCA and its surrounding range (covering at least one driving circuit region PDCA); FIG. 27 shows a schematic structural view of the second gate layer LG2 in a partial area of the display area (covering at least two driving circuit islands PDCC); FIG. 28 shows a schematic structural view of the third gate layer LG3 in a driving circuit region PDCA and its surrounding range (covering at least one driving circuit region PDCA); FIG. 29 shows a schematic structural view of the third gate layer LG3 in a partial area of the display area (covering at least two driving circuit islands PDCC); FIG. 30 shows a schematic structural view of the first source-drain metal layer LSD1 in a driving circuit region PDCA and its surrounding range (covering at least one driving circuit region PDCA); FIG. 31 shows a schematic structural view of the first source-drain metal layer LSD1 in a partial area of the display area (covering at least two driving circuit islands PDCC); FIG. 32 shows a schematic structural view of the second source-drain metal layer LSD2 in a driving circuit region PDCA and its surrounding range (covering at least one driving circuit region PDCA); and FIG. 33 shows a schematic structural view of the second source-drain metal layer LSD2 in a partial area of the display area (covering at least two driving circuit islands PDCC).

Referring to FIG. 19 to FIG. 33, a driving circuit island PDCC may include eight driving circuit regions PDCA arranged in two rows and four columns; a wiring space PDCG is formed between the driving circuit islands PDCC, and the wiring space PDCG includes the row gap CC between two adjacent rows of driving circuit islands PDCC and the column gap DD between two adjacent columns of driving circuit islands PDCC. In some embodiments, the first transition line TR1 is provided in the row gap CC, and the second transition line TR2 is provided in the column gap DD.

Referring to FIG. 19 to FIG. 33, the driving circuits are arranged into a plurality of driving circuit groups, where each driving circuit group includes two driving circuits adjacent in the first direction, and these two driving circuits are arranged in a mirrored manner.

The film layer structure of the driving circuit according to one example is further introduced as follows.

Referring to FIG. 19 and FIG. 20, the light-shielding layer LBSM is provided with light-shielding blocks BSMP in one-to-one correspondence to the channel regions T3A of the respective driving transistors T3, and light-shielding lines BSML connecting the respective light-shielding blocks BSMP. Herein, the light-shielding block BSMP may overlap with the corresponding channel region T3A of the driving transistor T3, thereby blocking the light irradiated to the channel region T3A of the driving transistor T3 and, thus, keeping the electrical characteristics of T3 stable. The light-shielding lines BSML are arranged along the first and second directions and connect adjacent light-shielding blocks BSMP, so that the light-shielding layer LBSM is meshed as a whole. In some embodiments of this disclosure, the material of the light-shielding layer LBSM is metal, so that the light-shielding layer LBSM may also have an electromagnetic shielding effect.

Referring to FIG. 21 and FIG. 22, the low-temperature polysilicon semiconductor layer LPoly is provided with the sources, drains and channel regions of transistors such as the driving transistor T3, the data writing transistor T4, the first light emission control transistor T5, the second light emission control transistor T6, and the electrode reset transistor T7. In some embodiments, the channel region T4A of the data writing transistor T4 and the channel region T5A of the first light emission control transistor T5 are arranged along the second direction H2, and the channel region T5A of the first light emission control transistor T5 and the channel region T6A of the second light emission control transistor T6 are arranged along the first direction H1. Along the first direction H1, the channel region T3A of the driving transistor T3 and the channel region T7A of the electrode reset transistor T7 are located between the channel region T5A of the first light emission control transistor T5 and the channel region T6A of the second light emission control transistor T6. Along the second direction H2, the channel region T7A of the electrode reset transistor T7 and the channel region T3A of the driving transistor T3 are located on both sides of the channel region T5A of the first light emission control transistor T5. In some embodiments, the drain T4D of the data writing transistor T4, the drain T5D of the first light emission control transistor T5, and the source T3S of the driving transistor T3 are connected, the drain T3D of the driving transistor T3 is electrically connected to the drain T6D of the second light emission control transistor T6, and the drain T7D of the electrode reset transistor T7 is electrically connected to the source T6S of the second light emission control transistor T6. In some embodiments, in two adjacent rows of driving circuits, the channel region T7A of the electrode reset transistor T7 in the upper row of driving circuits is arranged adjacent to the channel region T4A of the data writing transistor T4 in the lower row of driving circuits. The low-temperature polysilicon semiconductor layer LPoly is also provided with auxiliary line(s) PDUMMY located in the column gap DD, so as to ensure the process uniformity of LPoly during preparation.

Referring to FIG. 24 and FIG. 25, the first gate layer LG1 is provided with a second scanning line GL2, an enable signal line EML and a first electrode CP1 of the storage capacitor C. In some embodiments, the second scanning line GL2 extends along the first direction H1 and can be used for loading the second scanning signal G2. The second scanning line GL2 may overlap with the channel region T4A of the data writing transistor T4, and the overlapping part is reused as the gate of the data writing transistor T4. The second scanning line GL2 may also overlap the channel region T7A of the electrode reset transistor T7 in the driving circuit of the upper row, and the overlapping part is reused as the gate of the electrode reset transistor T7 in the driving circuit of the upper row. In this way, the electrode reset control line RL2 connected to the driving circuit of the upper row and the second scanning line GL2 connected to the driving circuit of the lower row are the same line. In this way, the electrode reset control signal Re2 of the driving circuit in the upper row and the second scanning signal G2 of the driving circuit in the lower row may be the same signal. The enable signal line EML extends along the first direction H1 and overlaps sequentially with the channel region T5A of the first light emission control transistor T5 and the channel region T6A of the second light emission control transistor T6, so as to be reused as the gate of the first light emission control transistor T5 and the gate of the second light emission control transistor T6. The enable signal line EML can be used to load the enable signal EM. The first electrode CP1 of the storage capacitor C overlaps with the channel region T3A of the driving transistor T3, so as to be reused as the gate of the driving transistor T3.

Referring to FIG. 26 and FIG. 27, the second gate layer LG2 is provided with a capacitor initialization voltage line Vinit1L, a lower capacitor reset control line RL11, a lower first scanning line GL11 and a second electrode CP2 of the storage capacitor C. In some embodiments, the capacitor initialization voltage line Vinit1L extends along the first direction H1 and can be used for loading the capacitor reset voltage Vinit1. The lower capacitor reset control line RL11 extends along the first direction H1 and can be used for loading the capacitor reset control signal Re1. The lower first scanning line GL11 extends along the first direction H1 and can be used for loading the first scanning signal G1. The second electrode CP2 of the storage capacitor C overlaps the first electrode CP1 of the storage capacitor C, and is provided with an avoidance hole HC that exposes a partial area of the first electrode CP1 of the storage capacitor C.

Referring to FIG. 21 and FIG. 23, the metal oxide semiconductor layer LOxide is provided with sources, drains and channel regions of the capacitor reset transistor T1 and the threshold compensation transistor T2. In some embodiments, along the second direction H2, the channel region TIA of the capacitor reset transistor T1 is located on a side of the channel region T2A of the threshold compensation transistor T2 away from the channel region T3A of the driving transistor T3, and the channel region T2A of the threshold compensation transistor T2 and the channel region T5A of the first light emission control transistor T5 are located on both sides of the channel region T3A of the driving transistor T3. Along the first direction H1, the channel region T4A of the data writing transistor T4 and the channel region TIA of the capacitor reset transistor T1 of the driving circuit in the lower row are located on both sides of the channel region T7A of the electrode reset transistor T7 of the driving circuit in the upper row. The drain TID of the capacitor reset transistor T1 and the drain T2D of the threshold compensation transistor T2 are connected to each other.

In some embodiments, the channel region TIA of the capacitor reset transistor T1 overlaps with the lower capacitor reset control line RL11, so that at least part of the overlapping portion between the lower capacitor reset control line RL11 and the channel region TIA of the capacitor reset transistor T1 can be reused as the first gate of the capacitor reset transistor T1. The lower first scanning line GL11 overlaps with the channel region T2A of the threshold compensation transistor T2, so that at least part of the overlapping portion between the lower first scanning line GL11 and the channel region T2A of the threshold compensation transistor T2 can be reused as the first gate of the threshold compensation transistor T2. In some embodiments, an orthographic projection of the channel region TIA of the capacitor reset transistor T1 on the second gate layer is located within the lower capacitor reset control line RL11, so that the lower capacitor reset control line RL11 can sufficiently shield light for the channel region TIA of the capacitor reset transistor T1. In some embodiments, an orthographic projection of the channel region T2A of the threshold compensation transistor T2 on the second gate layer is located within the lower first scanning line GL11, so that the lower first scanning line GL11 can sufficiently shield light for the channel region T2A of the threshold compensation transistor T2.

Referring to FIG. 28 and FIG. 29, the third gate layer LG3 includes an upper capacitor reset control line RL12 and an upper first scanning line GL12. In some embodiments, the upper capacitor reset control line RL12 extends along the first direction H1 and can be used for loading the capacitor reset control signal Re1. The upper first scanning line GL12 extends along the first direction H1 and can be used for loading the first scanning signal G1. In some embodiments, the upper capacitor reset control line RL12 overlaps with the channel region TIA of the capacitor reset transistor T1, and the overlapping part is reused as the second gate of the capacitor reset transistor T1. The upper first scanning line GL12 overlaps with the channel region T2A of the threshold compensation transistor T2, and the overlapping part is reused as the second gate of the threshold compensation transistor T2. In this way, the gate of the capacitor reset transistor T1 includes the first gate and the second gate of the capacitor reset transistor T1; and the gate of the threshold compensation transistor T2 includes the first gate and the second gate of the threshold compensation transistor T2.

Referring to FIG. 21, FIG. 24 and FIG. 26, the low-temperature polysilicon semiconductor layer LPoly, the first gate layer LG1, the second gate layer LG2, and the metal oxide semiconductor layer LOxide may be electrically connected to the first source-drain metal layer LSD1 through via holes. connect. In this disclosure, when two conductive film layers are connected by a via hole, the lower conductive film layer (the film layer close to the base substrate BP) has a lower via area aligned with a position of the via hole, and the upper conductive film layer (the film layer away from the base substrate BP) has an upper via area aligned with the position of the via hole. The upper via area of the upper conductive film layer is directly electrically connected with the lower via area of the lower conductive film layer through the via hole.

Referring to FIG. 21, the low-temperature polysilicon semiconductor layer LPoly may be provided with a first lower via area HA1 to a fifth lower via area HA5. The first lower via area HA1 is located at the source T4S of the data writing transistor T4, the second lower via area HA2 is located at the source T5S of the first light emission control transistor T5, the third lower via area HA3 is located at the drain T6D of the second light emission control transistor T6, the fourth lower via area HA4 is located at the source T7S of the electrode reset transistor T7, and the fifth lower via area HA5 is located at the source T6S of the second light emission control transistor T6. The metal oxide semiconductor layer LOxide may be provided with a sixth lower via area HA6 to an eighth lower via area HA8. The sixth lower via area HA6 is located at the source T2S of the threshold compensation transistor T2, the seventh lower via area HA7 is located at the drain T2D of the threshold compensation transistor T2, and the eighth lower via area HA8 is located at the source TIS of the capacitor reset transistor T1. Referring to FIG. 24 and FIG. 26, the second electrode CP2 of the storage capacitor C is provided with a ninth lower via area HA9, and the first electrode CP1 of the storage capacitor C is provided with a tenth lower via area HA10. The tenth lower via area HA10 is located in the avoidance gap HC of the second electrode CP2 of the storage capacitor C. An eleventh lower via area HA11 may be provided on the capacitor initialization voltage line Vinit1L. In some embodiments of this disclosure, in a symmetrically arranged driving circuit group, two driving circuits are connected to the capacitor initialization voltage line Vinit1L through the same via hole.

In this disclosure, the display panel is further provided with an electrode initialization voltage line. The electrode initialization voltage line is arranged in a meandering manner along the first direction H1 as a whole, so as to load the electrode reset voltage Vinit2. In some embodiments of this disclosure, the part of the electrode initialization voltage line located between the driving circuit islands PDCC may be bridged through the first gate layer LG1, and the remaining part may be routed through the first source-drain metal layer LSD1. In this way, the second transition line TR2 located on the first source-drain metal layer LSD1 may be arranged in the gap between the two driving circuits. In other words, referring to FIG. 24, FIG. 25, FIG. 30 and FIG. 31, the electrode initialization voltage line may include a second initialization line Vinit2L2 located on the first source-drain metal layer LSD1, and a first initialization line Vinit2L1 located on the first gate layer LG1. The first initialization line Vinit2L1 is located in the gap between the driving circuit islands PDCC, and the second initialization line electrode Vinit2L2 is basically located in the driving circuit island PDCC. An end of the first initialization line Vinit2L1 is provided with a twelfth lower via area HA12, an end of the second initialization line Vinit2L2 is provided with a twelfth upper via area HB12 overlapping with the twelfth lower via area HA12, and the twelfth lower via area HA12 is connected to the twelfth upper via area HB12 through a via hole. The second initialization line Vinit2L2 is provided with a fourth upper via area HB4 overlapping with the fourth lower via area HA4, and the fourth lower via area HA4 is connected to the fourth upper via area HB4 through a via hole. In this way, the source T7S of the electrode reset transistor T7 is electrically connected to the electrode initialization voltage line. Alternatively, in some other embodiments of this disclosure, the electrode initialization voltage lines may all be provided in the first source-drain metal layer LSD1.

Referring to FIG. 30 and FIG. 31, the first source-drain metal layer LSD1 is further provided with a first conductive structure ML1 to a sixth conductive structure ML6. The first conductive structure ML1 is provided with a first upper via area HB1 and a thirteenth lower via area HA13, where the first upper via area HB1 overlaps with the first lower via area HA1 and is connected thereto through a via hole. The second source-drain metal layer LSD2 is provided with a data line DL extending along the second direction H2, and the data line DL is used for loading the driving data signal Da. The data line DL is provided with a thirteenth upper via area HB13 overlapping with the thirteenth lower via area HA13, and the thirteenth upper via area HB13 is connected to the thirteenth lower via area HA13 through a via hole. In this way, the source T4S of the data writing transistor T4 is connected to the data line DL through the first conductive structure ML1.

The second conductive structure ML2 is provided with a second upper via area HB2, a ninth upper via area HB9 and a fourteenth lower via area HA14. The second upper via area HB2 overlaps with the second lower via area HA2 and is connected thereto through a via hole, and the ninth upper via area HB9 overlaps with the ninth lower via area HA9 and is connected thereto through a via hole. The second source-drain metal layer LSD2 is provided with a power supply line VDDL extending along the second direction H2, and the power supply line VDDL is used for loading the power supply voltage VDD. The power supply line VDDL is provided with a fourteenth upper via area HB14 overlapping with the fourteenth lower via area HA14, and the fourteenth upper via area HB14 is connected to the fourteenth lower via area HA14 through a via hole. In this way, the second electrode CP2 of the storage capacitor C, the power supply line VDDL and the source T5S of the first light emission control transistor T5 are electrically connected to each other through the second conductive structure ML2.

The third conductive structure ML3 is provided with a tenth upper via area HB10 and a seventh upper via area HB7. The tenth upper via area HB10 overlaps with the tenth lower via area HA10 and is connected thereto through a via hole, and the seventh upper via area HB7 overlaps with the seventh lower via area HA7 and is connected thereto through a via hole. In this way, the drain TID of the capacitor reset transistor T1 and the drain T2D of the threshold compensation transistor T2 are electrically connected to the first electrode CP1 (reused as the gate of the driving transistor T3) of the storage capacitor C through the third conductive structure ML3.

The fourth conductive structure ML4 is provided with an eighth upper via area HB8 and an eleventh upper via area HB11, the eighth upper via area HB8 overlaps with the eighth lower via area HA8 and is connected thereto through a via hole, and the eleventh upper via area HB11 overlaps with the eleventh lower via area HA11 and is connected thereto through a via hole. In this way, the capacitor initialization voltage line Vinit1L is electrically connected to the source TIS of the capacitor reset transistor T1 through the fourth conductive structure ML4.

The fifth conductive structure ML5 is provided with a fifth upper via area HB5 and a sixth upper via area HB6, the fifth upper via area HB5 overlaps with the fifth lower via area HA5 and is connected thereto through a via hole, and the sixth upper via area HB6 overlaps with the sixth lower via area HA6 and is connected thereto through a via hole. In this way, the drain T3D of the driving transistor T3 is electrically connected to the source T2S of the threshold compensation transistor T2 through the fifth conductive structure ML5.

The sixth conductive structure ML6 is provided with a third upper via area HB3 and a fifteenth lower via area HA15, where the third upper via area HB3 overlaps with the third lower via area HA3 and is connected thereto through a via hole. Referring to FIG. 32 and FIG. 33, the second source-drain metal layer LSD2 is provided with a transition electrode PA, where the transition electrode PA is used for electrical connection with the pixel electrode of the sub-pixel. The transition electrode PA is provided with a fifteenth upper via area HB15 overlapping with the fifteenth lower via area HA15, and the fifteenth lower via area HA15 is connected to the fifteenth upper via area HB15 through a via hole. In this way, the transition electrode PA is electrically connected to the drain T6D of the second light emission control transistor T6 through the sixth conductive structure ML6, so that the sub-pixel is electrically connected to the drain T6D of the second light emission control transistor T6.

Referring to FIG. 30, the first conductive structure ML1 and the fourth conductive structure ML4 are located on one side of the second initialization line Vinit2L2, and the second conductive structure ML2, the third conductive structure ML3, the fifth conductive structure ML5 and the sixth conductive structure ML6 are located on the other side of the second initialization line Vinit2L2.

Referring to FIG. 30, the first conductive structure ML1 to the sixth conductive structure ML6 of the driving circuit are located in the driving circuit region PDCA corresponding to the driving circuit. In some embodiments, a rectangular region where the first conductive structure ML1 to the sixth conductive structure ML6 of the driving circuit are distributed may be used to define the driving circuit region PDCA corresponding to the driving circuit, so that T1 to T6 of the driving circuit are located in the driving circuit region PDCA corresponding to the driving circuit, and T7 of the driving circuit is located in a driving circuit region PDCA corresponding to a driving circuit in the lower row.

As follows, taking display panels with different pixel densities as an example, the arrangement of the transition line TRs according to this disclosure will be further explained and illustrated.

In the display panel of this example, the driving circuits arranged in the same row may form a plurality of driving circuit groups in groups of two, and two driving circuits in one driving circuit group may be arranged in a mirrored manner. Four driving circuit groups in two adjacent rows and two adjacent columns form into a driving circuit island PDCC. In the display panel of this example, in order to meet process requirements and the like, the minimum size of the driving circuit group in the first direction H1 may reach 49 microns.

Taking half of the first display area AA1 on either side of the central axis MM of the display area AA as an arrangement area, the first display area AA1 is divided into two arrangement areas located on both sides of the central axis MM. In this example, only one of the arrangement areas is taken as an example to explain and illustrate the arrangement of the data lines DL and the transition lines TR in one arrangement area. In the two arrangement areas, the arrangements of the data lines DL and the transition lines TR may be symmetrical with respect to the central axis MM, or may be different. Preferably, in the two arrangement areas, the arrangement of the data lines DL and the transition lines TR may be symmetrical with respect to the central axis MM.

In this example, in one arrangement area, the number of data lines DL is n. Herein, in the order from outside to inside, the i-th data line DL is denoted as data line DL(i). In one arrangement area, the number of second data lines DL2 is x, and the number of first data lines DL1 is n−x. In other words, the data lines DL(1) to DL(x) are the second data lines DL2, and the data lines DL(x+1) to DL(n) are the first data lines DL1. In one arrangement area, a second transition line TR2 of the transition line TR connected to the data line DL(i) may be denoted as the second transition line TR(i).

In the display panel of the first example, the pixel density of the display panel is not higher than 410 PPI. The minimum size of the driving circuit group in the first direction H1 may be compressed to 49 microns. In this way, the width of the column gap DD of the driving circuit island PDCC in the first direction H1 may reach more than 13 microns. Referring to FIG. 15, the gap between the driving circuit island PDCC columns may accommodate at most six second transition lines TR2. Further, the six second transition lines TR2 in a second transition line group TR2S may be alternately distributed in the first source-drain metal layer LSD1 and the second source-drain metal layer LSD2 in sequence.

In the display panel of this example, the lower end of the first data line DL1 is connected to the corresponding pad connection line FA so as to be connected to the bonding area. The lower end of the second data line DL2 is not connected to the pad connection line FA, but is connected to each transition line TR in one-to-one correspondence. The second transition lines TR2 of respective transition lines TR are provided in the first display area AA1, and an end (the lower end), near the bonding end, of the second transition line TR2 is connected to the pad connection line FA to be connected to the bonding area. Herein, at least part of the second transition lines TR2 are provided in the gap between the driving circuit islands PDCC.

As a further example, referring to FIG. 15, along the direction from the outside to the inside, the second transition lines TR2 and the first data lines DL1 in an arrangement area may be arranged in the following order: one second transition line group TR2S, four first data lines DL1, one second transition line group TR2S, four first data lines DL1, . . . the last second transition line group TR2S, and the remaining first data lines DL1. Herein, except for the last second transition line group TR2S, the other second transition line groups TR2S each has six second transition lines TR2; and the number of second transition lines TR2 in the last second transition line group TR2S does not exceed 6. Exemplarily, along the direction from the outside to the inside, the transition lines TR and the first data lines DL1 in an arrangement area may be arranged in the following order: second transition line TR(1) to second transition line TR(6), data line DL(x+1) to data line DL(x+4), second transition line TR(7) to second transition line TR(12), data line DL(x+5) to data line DL(x+8) . . . second transition line TR(x), and the remaining first data line(s) DL1.

In some other embodiments of the display panel of the first example, the number of transition lines TR may exceed the second data lines DL2, so that the transition lines TR are electrically connected to the respective data lines DL in one-to-one correspondence. In this way, the ends (lower ends) of the second data lines DL2 and the first data lines DL1 near the bonding end are not directly electrically connected to the pad connection lines FA, but are electrically connected to the pad connection lines FA through the transition lines TR. In this example, the respective second transition lines TR2 may be arranged in the first display area AA1 and arranged in the same order as the respectively connected data lines DL in the first direction H1. Specifically, in an arrangement area, along the direction from the outside to the inside, the second transition lines TR2 may be arranged in the following order: second transition line TR(1), second transition line TR(2), second transition line TR(3), second transition line TR(4) . . . second transition line TR(n).

In the display panel of a second example, the pixel density of the display panel is 410-425 PPI. The minimum size of the driving circuit group in the first direction H1 can be compressed to 49 microns. In this way, the column gap DD of the driving circuit islands PDCC in the first direction H1 may reach 10.8 microns to 12.2 microns. Referring to FIG. 14, the gap between the driving circuit island PDCC columns can accommodate up to five second transition lines TR2. In an optional manner, five second transition lines TR2 in a second transition line group TR2S may be alternately distributed in the first source-drain metal layer LSD1 and the second source-drain metal layer LSD2. For example, two of them are in the first source-drain metal layer LSD1 and three are in the second source-drain metal layer LSD2, or three of them are in the first source-drain metal layer LSD1 and two are in the second source-drain metal layer LSD2. In another optional manner, the five second transition lines TR2 may all be provided in the second source-drain metal layer LSD2.

In the display panel of this example, one end (lower end) of the first data line DL1 close to the bonding end is connected to the pad connection line FA, so as to be connected to the bonding area. One end of the second data line DL2 close to the bonding area is not connected to the pad connection line FA, but is connected to each transition line TR in one-to-one correspondence. The second transition line TR2 of each transition line TR is provided in the first display area AA1, and the end of the second transition line TR2 close to the bonding end is connected to the pad connection line FA, so as to be connected to the bonding area. In some embodiments, at least part of the second transition lines TR2 is provided in the gap between the driving circuit islands PDCC.

As a further example, along the direction from the outside to the inside, the transition lines TR and the first data lines DL1 in an arrangement area may be arranged in the following order: one second transition line group TR2S, four first data lines line DL1, one second transition line group TR2S, four first data lines DL1, . . . the last second transition line group TR2S, and the remaining first data line(s) DL1. Herein, except for the last second transition line group TR2S, the other second transition line groups TR2S each has 5 second transition lines TR2; and the number of second transition lines TR2 in the last second transition line group TR2S does not exceed 5. Exemplarily, along the direction from the outside to the inside, the transition lines TR and the first data lines DL1 in an arrangement area may be arranged in the following order: second transition line TR(1) to second transition line TR(5), data line DL(x+1) to data line DL(x+4), second transition line TR(6) to second transition line TR(10), data line DL(x+5) to data line DL(x+8) . . . second transition line TR(x), and the remaining first data line(s) DL1.

In the display panel of a third example, the pixel density of the display panel is 425-430 PPI. The minimum size of the driving circuit group in the first direction H1 can be compressed to 49 microns. In this way, the column gap DD of the driving circuit islands PDCC in the first direction H1 may reach 10.1 microns. Referring to FIG. 12, the gap between the driving circuit island PDCC columns can accommodate up to four second transition lines TR2. In an optional manner, the four second transition lines TR2 may all be provided in the second source-drain metal layer LSD2.

In the display panel of this example, one end of the first data line DL1 close to the bonding end is connected to the pad connection line FA, so as to be connected to the bonding area. The end of the second data line DL2 close to the bonding area is not connected to the pad connection line FA, but is connected to the respective transition lines TR in one-to-one correspondence. The second transition line TR2 of each transition line TR is provided in the first display area AA1, and the end of the second transition line TR2 close to the bonding end is connected to the pad connection line FA, so as to be connected to the bonding area. In some embodiments, at least part of the second transition line TR2 is provided in the gap between the driving circuit islands PDCC.

As a further example, along the direction from the outside to the inside, the transition lines TR and the first data lines DL1 in an arrangement area may be arranged in the following order: one second transition line group TR2S, four first data lines line DL1, one second transition line group TR2S, four first data lines DL1, . . . the last second transition line group TR2S, and the remaining first data lines DL1. Herein, except for the last second transition line group TR2S, the other second transition line groups TR2S each has 4 second transition lines TR2; and the number of second transition lines TR2 in the last second transition line group TR2S does not exceed 4. Exemplarily, along the direction from the outside to the inside, the transition lines TR and the first data lines DL1 in an arrangement area may be arranged in the following order: second transition line TR(1) to second transition line TR(4), data line DL(x+1) to data line DL(x+4), second transition line TR(5) to second transition line TR(8), data line DL(x+5) to data line DL(x+8) . . . second transition line TR(x), and the remaining first data line(s) DL1.

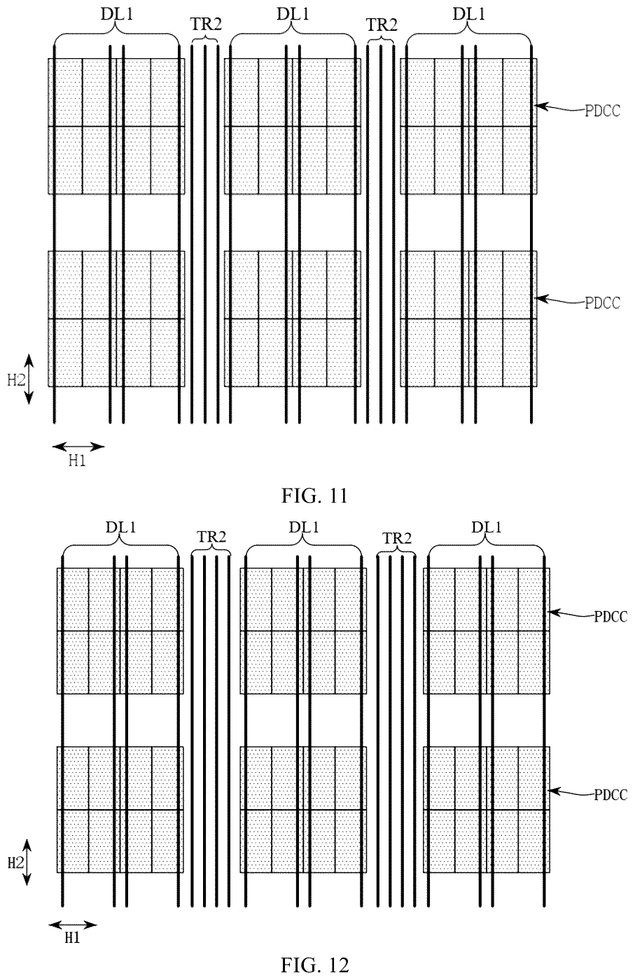

In the display panel of a fourth example, the pixel density of the display panel is 430-450 PPI. The minimum size of the driving circuit group in the first direction H1 can be compressed to 49 microns. In this way, the column gap DD of the driving circuit islands PDCC in the first direction H1 may reach 7.4 microns. Referring to FIG. 11, the gap between the driving circuit island PDCC columns may accommodate up to three second transition lines TR2. In an optional manner, the three second transition lines TR2 may all be provided in the second source-drain metal layer LSD2.

In the display panel of this example, one end of the first data line DL1 close to the bonding end is connected to the pad connection line FA, so as to be connected to the bonding area. The end of the second data line DL2 close to the bonding area is not connected to the pad connection line FA, but is connected to the respective transition lines TR in one-to-one correspondence. The second transition line TR2 of each transition line TR is provided in the first display area AA1, and the end of the second transition line TR2 close to the bonding end is connected to the pad connection line FA, so as to be connected to the bonding area. In some embodiments, at least part of the second transition line TR2 is provided in the gap between the driving circuit islands PDCC.

As a further example, along the direction from the outside to the inside, the transition lines TR and the first data lines DL1 in an arrangement area may be arranged in the following order: one second transition line group TR2S, four first data lines line DL1, one second transition line group TR2S, four first data lines DL1, . . . the last second transition line group TR2S, and the remaining first data line(s) DL1. Herein, except for the last second transition line group TR2S, the other second transition line groups TR2S each has 3 second transition lines TR2; and the number of second transition lines TR2 in the last second transition line group TR2S does not exceed 3. Exemplarily, along the direction from the outside to the inside, the transition lines TR and the first data lines DL1 in an arrangement area may be arranged in the following order: second transition line TR(1) to second transition line TR(3), data line DL(x+1) to data line DL(x+4), second transition line TR(4) to second transition line TR(6), data line DL(x+5) to data line DL(x+8) . . . second transition line TR(x), and the remaining first data line(s) DL1.

In the display panel of the fifth example, the pixel density of the display panel is 450-465 PPI. The minimum size of the driving circuit group in the first direction H1 can be compressed to 49 microns. In this way, the column gap DD of the driving circuit islands PDCC in the first direction H1 may reach 5.6 microns. Referring to FIG. 10, the gap between the driving circuit island PDCC columns may accommodate at most two second transition lines TR2. In an optional manner, the two second transition lines TR2 may both be provided in the second source-drain metal layer LSD2.

In the display panel of this example, one end of the first data line DL1 close to the bonding end is connected to the pad connection line FA, so as to be connected to the bonding area. The end of the second data line DL2 close to the bonding area is not connected to the pad connection line FA, but is connected to the respective transition lines TR in one-to-one correspondence. The second transition line TR2 of each transition line TR is provided in the first display area AA1, and the end of the second transition line TR2 close to the bonding end is connected to the pad connection line FA, so as to be connected to the bonding area. In some embodiments, at least part of the second transition line TR2 is provided in the gap between the driving circuit islands PDCC.

As a further example, along the direction from the outside to the inside, the transition lines TR and the first data lines DL1 in an arrangement area may be arranged in the following order: one second transition line group TR2S, four first data lines line DL1, one second transition line group TR2S, four first data lines DL1, . . . the last second transition line group TR2S, and the remaining first data line(s) DL1. Herein, except for the last second transition line group TR2S, the other second transition line groups TR2S each has 3 second transition lines TR2; and the number of second transition lines TR2 in the last second transition line group TR2S does not exceed 3. Exemplarily, along the direction from the outside to the inside, the transition lines TR and the first data lines DL1 in an arrangement area may be arranged in the following order: second transition line TR(1) to second transition line TR(2), data line DL(x+1) to data line DL(x+4), second transition line TR(3) to second transition line TR(4), data line DL(x+5) to data line DL(x+8) . . . second transition line TR(x), and the remaining first data line(s) DL1.

In the display panel of the fifth example, the pixel density of the display panel is 465-490 PPI. The minimum size of the driving circuit group in the first direction H1 can be compressed to 49 microns. In this way, the gap between the driving circuit island PDCCs in the first direction H1 may reach 2.8 microns. Referring to FIG. 9, the gap between the driving circuit island PDCC columns can accommodate at most one second transition line TR2, and this second transition line TR2 may be provided in the second source-drain metal layer LSD2.

In the display panel of this example, one end of the first data line DL1 close to the bonding end is connected to the pad connection line FA, so as to be connected to the bonding area. The end of the second data line DL2 close to the bonding area is not connected to the pad connection line FA, but is connected to each transition line TR in one-to-one correspondence. The second transition line TR2 of each transition line TR is provided in the first display area AA1, and the end of the second transition line TR2 close to the bonding end is connected to the pad connection line FA, so as to be connected to the bonding area. In some embodiments, at least part of the second transition line TR2 is provided in the gap between the driving circuit islands PDCC.

As a further example, along the direction from the outside to the inside, the transition lines TR and the first data lines DL1 in an arrangement area may be arranged in the following order: one second transition line group TR2S, four first data lines line DL1, one second transition line group TR2S, four first data lines DL1, . . . the last second transition line group TR2S, and the remaining first data line(s) DL1. Herein, each second transition line group TR2S has only one second transition line TR2.

Exemplarily, along the direction from the outside to the inside, the transition lines TR and the first data lines DL1 in an arrangement area may be arranged in the following order: second transition line TR(1), data line DL(x+1) to data line DL(x+4), second transition line TR(2), data line DL(x+5) to data line DL(x+8) . . . second transition line TR(x), data line DL(5x−3) to data line DL(n).

In the display panel of a sixth example, the pixel density of the display panel is not less than 490 PPI. By compressing the size of the driving circuit group in the transition area, it is difficult to form a sufficient gap between the driving circuit islands PDCC for laying the transition line TR. In this case, the display panel of this example may further be provided with a third source-drain metal layer, and the third source-drain metal layer is located between the second source-drain metal layer LSD2 and the pixel layer. The transition line TR may be provided in the third source-drain metal layer.

In some embodiments of the display panel according to this example, one end of the first data line DL1 close to the bonding end is connected to the pad connection line FA, so as to be connected to the bonding area. The end of the second data line DL2 close to the bonding area is not connected to the pad connection line FA, but is connected to each transition line TR in one-to-one correspondence. The second transition line TR2 of each transition line TR is provided in the first display area AA1, and the end of the second transition line TR2 close to the bonding end is connected to the pad connection line FA, so as to be connected to the bonding area. In this example, the transition line TR may be provided in a gap of the driving circuit, or may overlap with the driving circuit, which is not specifically limited in this disclosure.

In some other embodiments of the display panel according to this example, the number of transition lines TR exceeds the second data lines DL2, so that the transition lines TR are electrically connected to the respective data lines DL in one-to-one correspondence. In this way, the ends of the second data lines DL2 and the first data lines DL1 close to the bonding end are not directly electrically connected to the pad connections line FA, but are electrically connected to the pad connection lines FA through the electrically connected transition lines TR. In this example, the respective second transition lines TR2 may be arranged in the first display area AA1 and arranged in the same order as the respectively connected data lines DL in the first direction H1. Specifically, in an arrangement area, along the direction from the outside to the inside, the second transition lines TR2 may be arranged in the following order: second transition line TR(1), second transition line TR(2), second transition line TR(3), second transition line TR(4) . . . second transition line TR(n).

Other embodiments of this disclosure will be readily apparent to those skilled in the art from consideration of the specification and practice of the invention disclosed herein. This application is intended to cover any modification, use or adaptation of this disclosure, and these modifications, uses or adaptations follow the general principles of this disclosure and include common knowledge or conventional technical means in the art not disclosed in this disclosure. The specification and examples are to be considered exemplary only, with the true scope and spirit of the disclosure indicated by the appended claims.

1. A display panel, comprising a display area and a peripheral area at least partially surrounding the display area; wherein, along a first direction, the display area of the display panel comprises a first display area and a second display area located on both sides of the first display area; and the display panel comprises:
a plurality of pads located in the peripheral area;
a plurality of data lines located in the display area and extending along a second direction, wherein the plurality of data lines comprise a plurality of first data lines located in the first display area and a plurality of second data lines located in the second display area, and the plurality of first data lines are electrically connected to the plurality of pads; and
a plurality of transition lines located in the display area and electrically connected to the plurality of second data lines and the plurality of pads, wherein the transition lines comprise first transition lines extending along the first direction and second transition lines extending along the second direction;
wherein, at least one of the second transition lines is provided between two adjacent ones of the first data lines, and the first direction intersects with the second direction.

2. The display panel according to claim 1, wherein the second transition lines are arranged into a plurality of second transition line groups, and each of the second transition line groups comprises at least two adjacent ones of the second transition lines;
the plurality of first data lines are arranged into a plurality of first data line groups, and each of the plurality of first data line groups comprises multiple adjacent ones of the first data lines;
in at least a partial area of the first display area, the first data line groups and the second transition line groups are alternately arranged one by one.

3. The display panel according to claim 1, wherein the second transition lines comprise first sub-lines and second sub-lines, and the first sub-lines and the second sub-lines are arranged on different conductive layers;
in at least a partial area of the first display area, the first sub-lines and the second sub-lines are alternately arranged.

4. The display panel according to claim 1, further comprising a plurality of pad connection lines;
wherein the plurality of pad connection lines are located in the peripheral area and electrically connected to the plurality of pads; the second transition lines are electrically connected to the plurality of pads through the pad connection lines; and the first data lines are electrically connected to the plurality of pads through the pad connecting lines.

5. The display panel according to claim 1, wherein a side of the second display area close to the plurality of pads is provided with an arc-shaped top corner.

6. The display panel according to claim 1, wherein the display area is arranged symmetrically with respect to a central axis extending along the second direction;
in two adjacent ones of the second data lines, compared with one of the second transition lines corresponding to one of the two adjacent ones of the second data lines closer to the central axis, another one of the second transition lines corresponding to another one of the two adjacent ones farther away from the central axis is arranged farther away from the central axis.

7. The display panel according to claim 1, wherein the display area is arranged symmetrically with respect to a central axis extending along the second direction;
in two adjacent ones of the second data lines, compared with one of the first transition lines corresponding to one of the two adjacent ones closer to the central axis, another one of the first transition lines corresponding to another one of the two adjacent ones farther away from the central axis is arranged closer to the pads.

8. The display panel according to claim 1, further comprising a base substrate, a driving circuit layer and a pixel layer stacked in sequence, wherein the driving circuit layer comprises a transistor layer and a source-drain metal layer stacked with each other, and the source-drain metal layer is sandwiched between the transistor layer and the pixel layer;
the transition lines are provided on the source-drain metal layer.

9. The display panel according to claim 8, wherein the source-drain metal layer comprises a first source-drain metal layer and a second source-drain metal layer sequentially stacked on a side of the transistor layer away from the base substrate; the data lines are provided on the second source-drain metal layer;
the first transition lines are provided on the first source-drain metal layer; and the second transition lines are provided on the second source-drain metal layer and/or the first source-drain metal layer.

10. The display panel according to claim 9, wherein the transistor layer is provided with a gate layer;
the driving circuit layer further comprises an electrode initialization voltage line extending along the first direction; the electrode initialization voltage line is configured to load an electrode reset voltage for resetting sub-pixels of the display panel; the electrode initialization voltage line comprises a first initialization line and a second initialization line alternately connected; the first initialization line is provided on the gate layer; and the second initialization line is provided on the first source-drain metal layer;
part of the second transition lines are provided on the first source-drain metal layer, and the second transition lines located on the first source-drain metal layer overlap with the first initialization line.

11. The display panel according to claim 8, wherein the source-drain metal layer comprises a first source-drain metal layer, a second source-drain metal layer and a third source-drain metal layer sequentially stacked on a side of the transistor layer away from the base substrate; the data lines are provided on the second source-drain metal layer; and the transition lines are provided on the third source-drain metal layer.

12. The display panel according to claim 8, wherein the transistor layer is provided with thin film transistors of driving circuits, and the transition lines do not overlap with the thin film transistors.

13. The display panel according to claim 12, wherein the driving circuit layer comprises driving circuit islands distributed in an array, and any one of the driving circuit islands comprises one or more driving circuit regions corresponding to respective one of the driving circuits; at least part of the thin film transistors of the driving circuits are provided in corresponding ones of the driving circuit regions;
the transition lines are provided in a gap between the driving circuit islands.

14. The display panel according to claim 13, wherein, among two adjacent ones of the driving circuits in the second direction, at least one thin film transistor of the driving circuit in an upper row is located in one of the driving circuit regions corresponding to the driving circuit in a lower row, and remaining thin film transistors of the driving circuit in the upper row are located in one of the driving circuit regions corresponding to the driving circuit in the upper row.

15. The display panel according to claim 13, wherein the driving circuits are arranged into a plurality of driving circuit groups, and each of the driving circuit groups comprises two of driving circuits that are adjacent and mirrored along the first direction.

16. The display panel according to claim 13, wherein the driving circuit regions in the driving circuit islands are arranged in multiple rows and multiple columns.

17. The display panel according to claim 16, wherein the driving circuit regions in the driving circuit islands are arranged in two rows and four columns.

18. The display panel according to claim 13, wherein the transition lines comprise first transition lines extending along the first direction and second transition lines extending along the second direction;
a number of the second transition lines between two adjacent columns of the driving circuit islands is no more than six.

19. The display panel according to claim 18, wherein the display area is arranged symmetrically with respect to a central axis extending along the second direction, and the first display area comprises two arrangement areas respectively located on both sides of the central axis;
the second transition lines are arranged into a plurality of second transition line groups; respective second transition lines in any one of the second transition line groups are arranged adjacently in sequence and located between two adjacent columns of the driving circuit islands; any two adjacent ones of the second transition line groups are separated by a column of the driving circuit islands;
any one of the second transition line groups comprises one or more of the second transition lines.

20-26. (canceled)

27. A display device, comprising a display panel, wherein the display panel comprises a display area and a peripheral area at least partially surrounding the display area; wherein, along a first direction, the display area of the display panel comprises a first display area and a second display area located on both sides of the first display area; and the display panel comprises:
a plurality of pads located in the peripheral area;
a plurality of data lines located in the display area and extending along a second direction, wherein the plurality of data lines comprise a plurality of first data lines located in the first display area and a plurality of second data lines located in the second display area, and the plurality of first data lines are electrically connected to the plurality of pads; and
a plurality of transition lines located in the display area and electrically connected to the plurality of second data lines and the plurality of pads, wherein the transition lines comprise first transition lines extending along the first direction and second transition lines extending along the second direction;
wherein, at least one of the second transition lines is provided between two adjacent ones of the first data lines, and the first direction intersects with the second direction.
